(19) United States
(12) Patent Application Publication
(10) Pub. No.: US 2025/0167115 A1
(43) Pub. Date: May 22, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Jimo GU, Suwon-si (KR); Bumkyu KANG, Suwon-si (KR); Ahreum LEE, Suwon-si (KR); Junhyoung KIM, Suwon-si (KR); Jiwon KIM, Suwon-si (KR); Sukkang SUNG, Suwon-si (KR)

(73) Assignee: Samsung Electronics Co., Ltd., Suwon-si (KR)

(21) Appl. No.: 18/925,771

(22) Filed: Oct. 24, 2024

(30) Foreign Application Priority Data
Nov. 22, 2023 (KR) 10-2023-0163589

(51) Int. Cl. H01L 23/528; H01L 23/00; H01L 23/522; H01L 23/532; H01L 25/065; H10B 12/00; H10B 41/35; H10B 41/41; H10B 43/35; H10B 43/40; H10B 80/00

(52) U.S. Cl. CPC H01L 23/5283; H01L 23/5226; H01L 23/53295; H01L 25/0657; H10B 12/482; H10B 12/50; H10B 41/35; H10B 41/41; H10B 43/35; H10B 43/40; H10B 80/00; H01L 24/13; H01L 24/48; H01L 2224/13023; H01L 2224/48148; H01L 2224/48228; H01L 2225/06506; H01L 2225/0651; H01L 2225/06562; H01L 2924/1436

(57) ABSTRACT

A semiconductor device may include a peripheral circuit structure first bonding pads connected to peripheral circuits on a semiconductor substrate; and a cell array structure including second bonding pads bonded to the first bonding pads. The cell array structure may include a separation structure penetrating a stack structure, vertical channel patterns penetrating the stack structure, a source conductive pattern connected to the vertical channel patterns on the stack structure, an upper dielectric layer covering the source conductive pattern, and an upper via that penetrates the upper dielectric layer. The stack structure may include interlayer dielectric layers and conductive patterns that are vertically alternately stacked. The separation structure may include a stop pattern on a dielectric pattern. The source conductive pattern may be in contact with a top surface of the stop pattern. The upper via may connect to the source conductive pattern on the stop pattern.

### CROSS-REFERENCE TO RELATED APPLICATION

This U.S. nonprovisional application claims priority under 35 U.S.C § 119 to Korean Patent Application No. 10-2023-0163589, filed on Nov. 22, 2023 in the Korean Intellectual Property Office, the disclosure of which is hereby incorporated by reference in its entirety.

### BACKGROUND

Inventive concepts relate to a semiconductor device and an electronic system including the same.

It may be necessary to have a semiconductor device capable of storing a large amount of data in an electronic system that requires data storage. Therefore, studies have been conducted to increase data storage capacity of the semiconductor device. For example, as an approach to increase data storage capacity of the semiconductor device, a semiconductor device has been suggested to include three-dimensionally arranged memory cells instead of two-dimensionally arranged memory cells.

### SUMMARY

Some embodiments of inventive concepts provide a semiconductor device with improved reliability and increased integration.

Some embodiments of inventive concepts provide an electronic system including a semiconductor device.

Aspects of inventive concepts are not limited to the mentioned above, and other aspects which have not been mentioned above will be clearly understood to those skilled in the art from the following description.

According to some embodiments of inventive concepts, a semiconductor device may include a semiconductor substrate; a peripheral circuit structure including a plurality of peripheral circuits on the semiconductor substrate and a plurality of first bonding pads connected to the peripheral circuits; and a cell array structure including a plurality of second bonding pads bonded to the first bonding pads. The cell array structure may include a stack structure, a separation structure penetrating the stack structure, a plurality of vertical channel patterns penetrating the stack structure, a source conductive pattern connected to the vertical channel patterns on the stack structure, an upper dielectric layer covering the source conductive pattern, and an upper via that penetrates the upper dielectric layer. The stack structure may include a plurality of interlayer dielectric layers and a plurality of conductive patterns that are vertically alternately stacked. The separation structure may include a dielectric pattern and a stop pattern on the dielectric pattern. The source conductive pattern may be in contact with a top surface of the stop pattern, and the upper via may connect to the source conductive pattern on the stop pattern.

According to some embodiments of inventive concepts, a semiconductor device may include a semiconductor substrate; a peripheral circuit structure including a plurality of peripheral circuits on the semiconductor substrate and a plurality of first bonding pads connected to the peripheral circuits; and a cell array structure including a plurality of second bonding pads bonded to the first bonding pads. The cell array structure may include a plurality of separation structures extending in a first direction, a stack structure between the plurality of separation structures, the stack structure including a plurality of interlayer dielectric layers and a plurality of conductive patterns that are vertically alternately stacked, a source conductive pattern on the stack structure, a plurality of vertical channel patterns penetrating the stack structure and connecting to the source conductive pattern; a plurality of bit lines extending in a second direction while crossing the stack structure and connecting to the vertical channel patterns, the second direction intersecting the first direction, an upper dielectric layer covering the source conductive pattern, an upper via penetrating the upper dielectric layer and connecting to the source conductive pattern, and a wiring pattern on the upper dielectric layer and connecting to the upper via. Each of the plurality of separation structures may include a dielectric pattern, a stop pattern on the dielectric pattern and adjacent to the source conductive pattern, and a spacer. The spacer may surround the dielectric pattern and at least a portion of the stop pattern. A vertical length of the stop pattern may be less than a vertical length of the dielectric pattern.

According to some embodiments of inventive concepts, an electronic system may include a semiconductor device including a peripheral circuit structure and a cell array structure on the peripheral circuit structure; and a controller electrically connected through an input/output pad to the semiconductor device, the controller being configured to control the semiconductor device. The peripheral circuit structure may include a plurality of peripheral circuits integrated on a semiconductor substrate and a plurality of first bonding pads connected to the peripheral circuits. The cell array structure may include a plurality of second bonding pads bonded to the first bonding pads. The cell array structure may include a stack structure, a separation structure penetrating the stack structure, a plurality of vertical channel patterns penetrating the stack structure, a source conductive pattern connected to the vertical channel patterns on the stack structure, an upper dielectric layer covering the source conductive pattern, and an upper via that penetrates the upper dielectric layer. The stack structure may include a plurality of interlayer dielectric layers and a plurality of conductive patterns that are vertically alternately stacked. The separation structure may include a dielectric pattern and a stop pattern on the dielectric pattern. The source conductive pattern may be in contact with a top surface of the stop pattern. The upper via may connect to the source conductive pattern on the stop pattern.

### BRIEF DESCRIPTION OF DRAWINGS

FIG. 1 illustrates a simplified schematic diagram showing an electronic system that includes a semiconductor device according to some embodiments of inventive concepts.

FIG. 2 illustrates a simplified perspective view showing an electronic system that includes a semiconductor device according to some embodiments of inventive concepts.

FIGS. 3 and 4 illustrate simplified cross-sectional views showing a semiconductor package according to some embodiments of inventive concepts.

FIG. 5 illustrates a plan view showing a semiconductor device according to some embodiments of inventive concepts.

FIG. 6A illustrates a cross-sectional view taken along line A-A′ of FIG. 5, showing a semiconductor device according to some embodiments of inventive concepts.

FIG. 6B illustrates a cross-sectional view taken along line B-B′ of FIG. 5, showing a semiconductor device according to some embodiments of inventive concepts.

FIG. 7A illustrates an enlarged view showing section P1 of FIG. 6A.

FIGS. 7B to 7E illustrate enlarged cross-sectional views showing section P1 according to some embodiments of inventive concepts.

FIG. 8 illustrates an enlarged view showing section P2 of FIG. 6A.

FIGS. 9 to 11, 12A, 12B, 12C, and 13 to 23 illustrate cross-sectional views taken along line A-A′ of FIG. 5, showing a method of fabricating a semiconductor device according to some embodiments of inventive concepts.

FIGS. 24A to 24C illustrate cross-sectional views showing a method of forming a separation structure in fabricating a semiconductor device according to some embodiments of inventive concepts.

FIGS. 25A to 25D illustrate cross-sectional views showing a method of forming a separation structure in fabricating a semiconductor device according to some embodiments of inventive concepts.

### DETAILED DESCRIPTION OF EMBODIMENTS

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”, “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

The following will now describe some embodiments of inventive concepts in conjunction with the accompanying drawings.

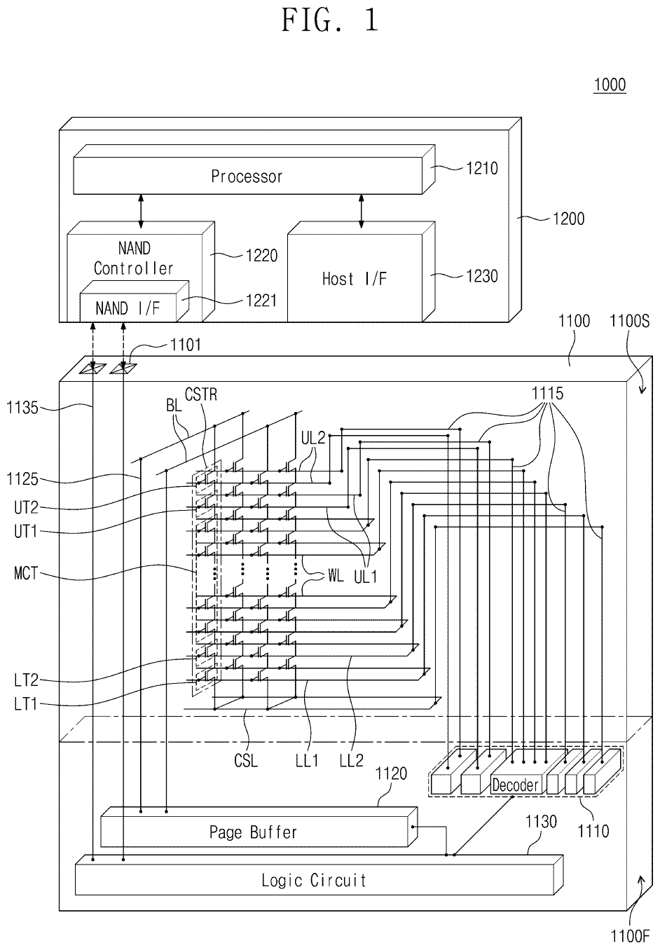

FIG. 1 illustrates a simplified schematic diagram showing an electronic system that includes a semiconductor device according to some embodiments of inventive concepts.

Referring to FIG. 1, an electronic system 1000 according to some embodiments of inventive concepts may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as an NAND Flash memory device. The semiconductor device 1100 may include a first structure 1100F and a second structure 1100S on the first structure 1100F. In some embodiments, the first structure 1100F may be disposed on a side of the second structure 1100S.

The first structure 1100F may be a peripheral circuit structure that includes a decoder circuit 1110, a page buffer 1120, and a logic circuit 1130. The second structure 1100S may be a memory cell structure that includes bit lines BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments.

In some embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some embodiments, the lower transistors LT1 and LT2 may include a lower erase control transistor LT1 and a ground selection transistor LT2 that are connected in series. The upper transistors UT1 and UT2 may include a string selection transistor UT1 and an upper erase control transistor UT2 that are connected in series. One or both of the lower and upper erase control transistors LT1 and UT1 may be employed to perform an erase operation in which a gate induced drain leakage (GIDL) phenomenon is used to erase data stored in the memory cell transistors MCT.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F toward the second structure 1100S. The bit lines BL may be electrically connected to the page buffer 1120 through second connection lines 1125 that extend from the first structure 1100F to the second structure 1100S.

In the first structure 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first structure 1100F to the second structure 1100S.

Although not shown, the first structure 1100F may include a voltage generator. The voltage generator may produce program voltages, read voltages, pass voltages, and verification voltages that are required for operating the memory cell strings CSTR. The program voltage may be relatively higher (e.g., about 20 V to about 40 V) than the read voltage, the pass voltage, and the verification voltage.

In some embodiments, the first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as program voltages applied to the word lines WL in a program operation. The page buffer 1120 may also include high-voltage transistors capable of withstanding high voltages.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on desired and/or alternatively predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

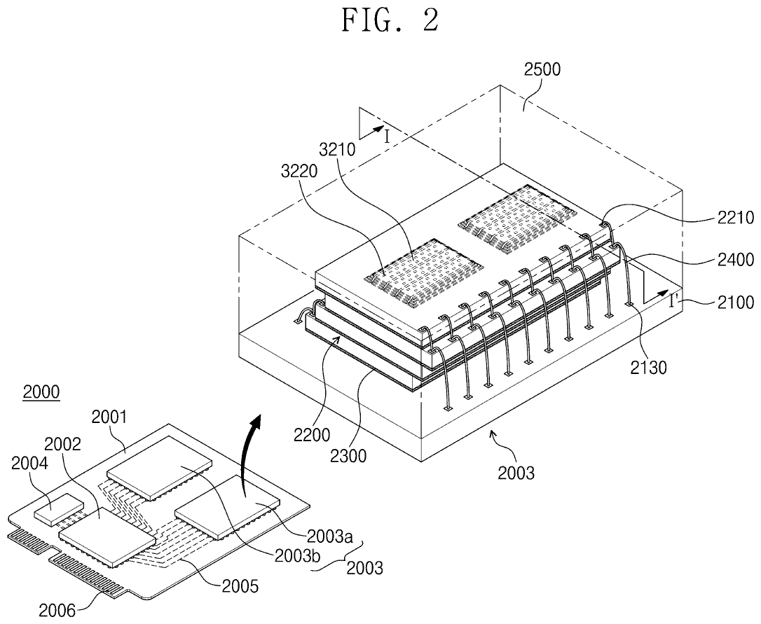

FIG. 2 illustrates a simplified perspective view showing an electronic system that includes a semiconductor device according to some embodiments of inventive concepts.

Referring to FIG. 2, an electronic system 2000 according to some embodiments of inventive concepts may include a mainboard 2001, and may also include a controller 2002, at least one semiconductor package 2003, and a dynamic random access memory (DRAM) 2004 that are mounted on the mainboard 2001. The semiconductor package 2003 and the DRAM 2004 may be connected to the controller 2002 through wiring patterns 2005 formed on the mainboard 2001.

The mainboard 2001 may include a connector 2006 including a plurality of pins that are coupled to an external host. The number and arrangement of the plurality of pins in the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PIC-Express), serial advanced technology attachment (SATA), and M-PHY for universal flash storage (UFS). In some embodiments, the electronic system 2000 may operate with power supplied through the connector 2006 from the external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

The package substrate 2100 may be a printed circuit board including upper pads 2130. Each of the semiconductor chips 2200 may include one or more input/output pads 2210. The input/output pad 2210 may correspond to the input/output pad 1101 of FIG. 1. Each of the semiconductor chips 2200 may include stack structures 3210 and vertical structures 3220. Each of the semiconductor chips 2200 may include a subsequently described semiconductor device according to some embodiments of inventive concepts.

In some embodiments, the connection structure 2400 may be a bonding wire that electrically connects the input/output pad 2210 to the upper pad 2130. Therefore, in each of the first and second semiconductor packages 2003a and 2003b, the semiconductor chips 2200 may be electrically connected to each other in a bonding wire manner, and may be electrically connected to the upper pads 2130 of the package substrate 2100. In some embodiments, in each of the first and second semiconductor packages 2003a and 2003b, the semiconductor chips 2200 may be electrically connected to each other through connection structures such as through silicon vias (TSV) instead of the connection structures 2400 shaped like bonding wires.

In some embodiments, the controller 2002 and the semiconductor chips 2200 may be included in a single package. For example, the controller 2002 and the semiconductor chips 2200 may be mounted on an interposer substrate other than the mainboard 2001, and may be connected to each other through wiring lines formed on the interposer substrate.

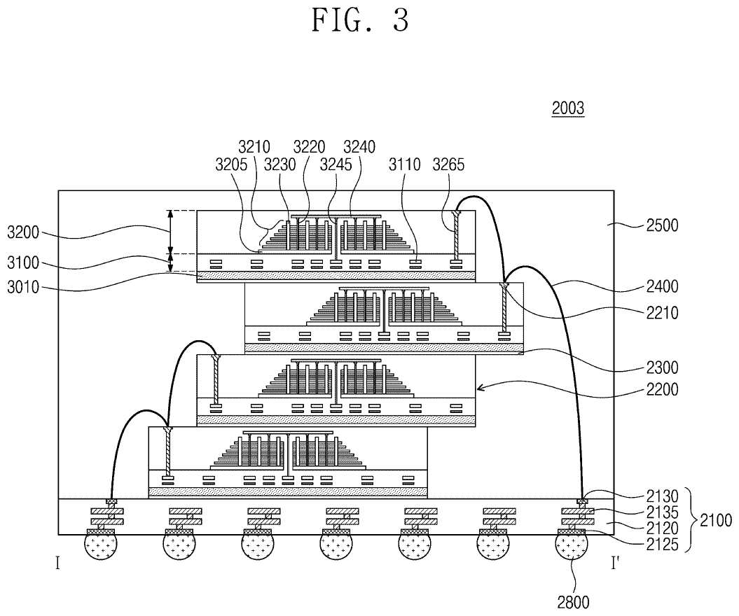

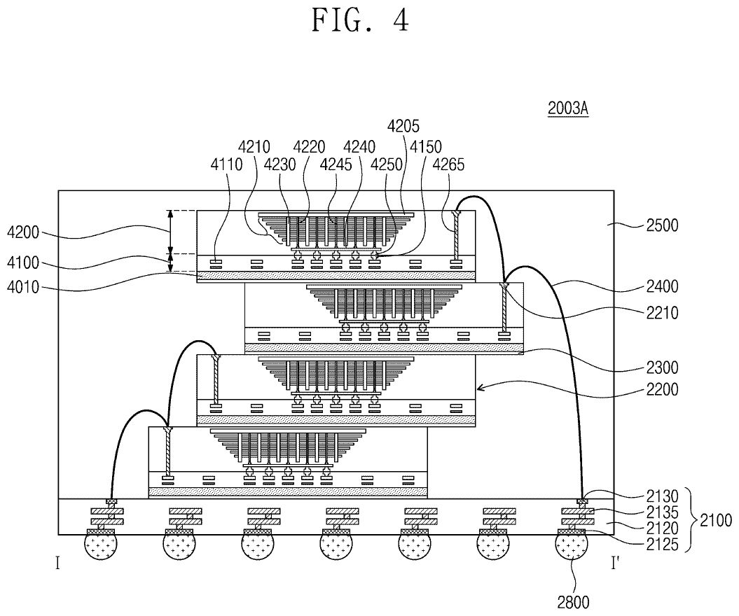

FIGS. 3 and 4 illustrate simplified cross-sectional views showing a semiconductor package according to some embodiments of inventive concepts. FIGS. 3 and 4 each depicts an example of the semiconductor package illustrated in FIG. 2, conceptually showing a section taken along line I-I′ of the semiconductor package illustrated in FIG. 2.

Referring to FIG. 3, a printed circuit board may be used as the package substrate 2100 of the semiconductor package 2003. The package substrate 2100 may include a package substrate body 2120, upper pads (see 2130 of FIG. 2) disposed on a top surface of the package substrate body 2120, lower pads 2125 disposed or exposed on a bottom surface of the package substrate body 2120, and internal lines 2135 by which the upper pads 2130 and the lower pads 2125 are electrically connected to each other in the package substrate body 2120. The upper pads 2130 may be electrically connected to the connection structures 2400. The lower pads 2125 may be connected through conductive connectors 2800 to the wiring patterns 2005 of the mainboard 2001 in the electronic system 2000, as shown in FIG. 2.

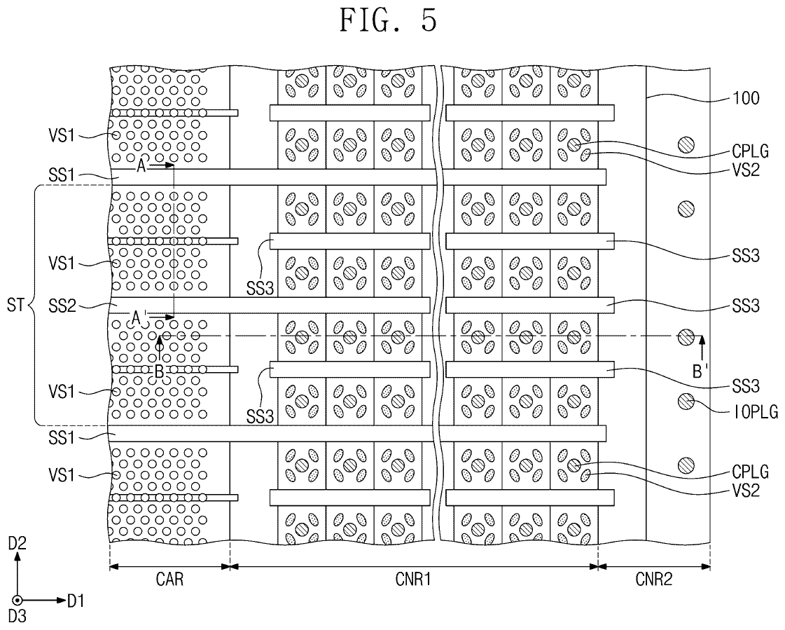

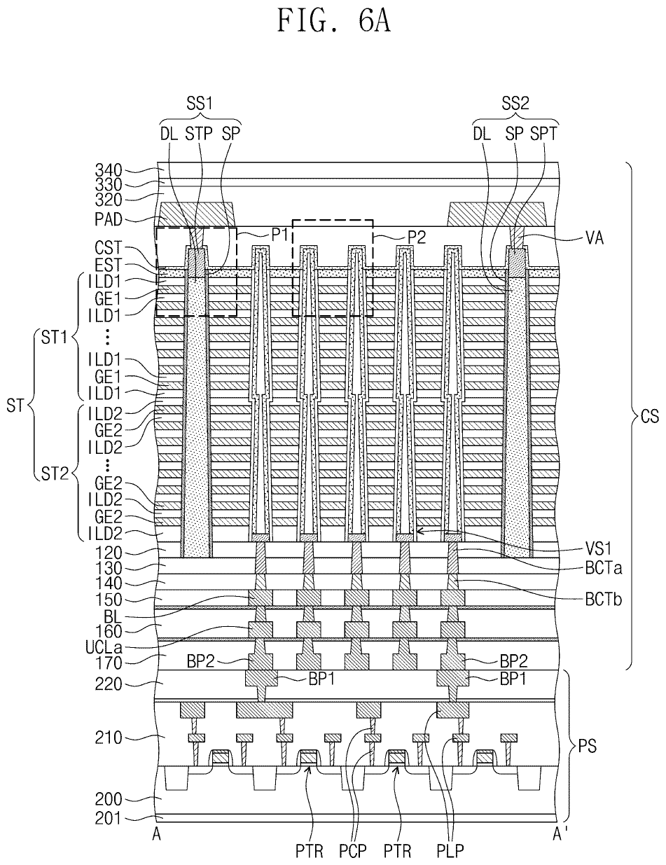

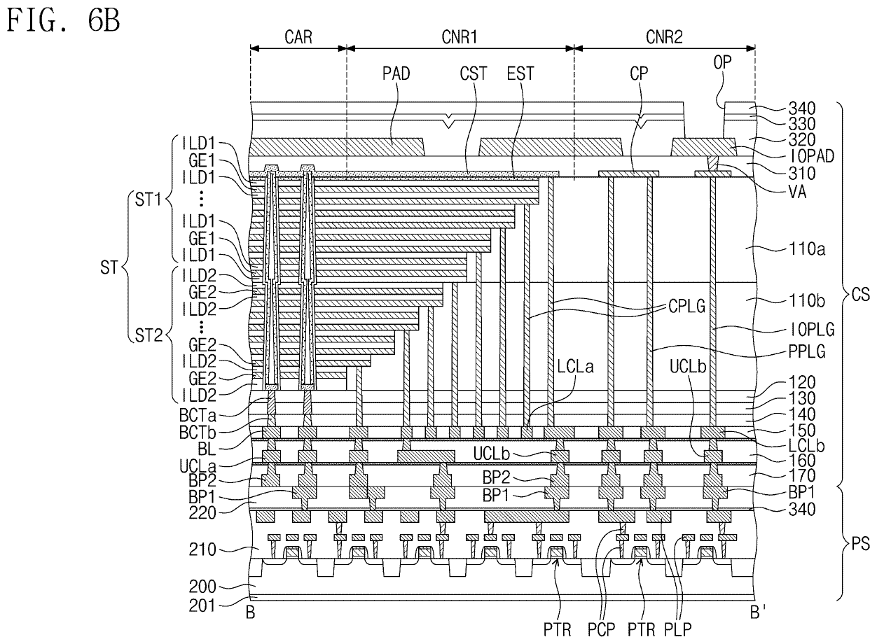

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a source structure 3205, a stack structure 3210 on the source structure 3205, vertical structures 3220 and separation structures 3230 that penetrates the stack structure 3210, bit lines 3240 electrically connected to the vertical structures 3220, and cell contact plugs electrically connected to corresponding word lines (see WL of FIG. 1) of the stack structure 3210. The separation structure 3230 may correspond to one of first, second, and third separation structures (see SS1, SS2, and SS3 of FIG. 5) which will be discussed below. The source structure 3205 may correspond to a source conductive pattern (see CST of FIG. 6), which will be discussed below.

Each of the semiconductor chips 2200 may include one or more through wiring lines 3245 that extend into the second structure 3200 and are electrically connected to the peripheral wiring lines 3110 of the first structure 3100. The through wiring line 3245 may be disposed outside the stack structure 3210 and may further be disposed to penetrate the stack structure 3210. Each of the semiconductor chips 2200 may further include one or more input/output pads (see 2210 of FIG. 2) electrically connected to the peripheral wiring lines 3110 of the first structure 3100.

Referring to FIG. 4, in a semiconductor package 2003A, each semiconductor chip 2200 may include a semiconductor substrate 4010, a first structure 4100 on the semiconductor substrate 4010, a second structure 4200 disposed on and wafer-bonded to the first structure 4100.

The first structure 4100 may include a peripheral circuit region including peripheral wiring lines 4110 and first bonding structures 4150. The second structure 4200 may include a source structure 4205, a stack structure 4210 between the source structure 4205 and the first structure 4100, vertical structures 4220 and separation structures 4230 that penetrate the stack structure 4210, and second bonding structures 4250 electrically connected to corresponding word lines (see WL of FIG. 1) of the stack structure 4210. For example, the second bonding structures 4250 may be electrically connected to corresponding vertical structures 4220 and corresponding word lines (see WL of FIG. 1) through the bit lines 4240 electrically connected to the vertical structures 4220 and through cell contact plugs electrically connected to the word lines WL. The first bonding structures 4150 of the first structure 4100 may be bonded to while being in contact with the second bonding structures 4250 of the second structure 4200. The first and second bonding structures 4150 and 4250 may have their bonding portions formed of, for example, copper (Cu).

The separation structure 4230 may correspond to one of first, second, and third separation structures (see SS1, SS2, and SS3 of FIG. 5) which will be discussed below. The source structure 4205 may correspond to a source conductive pattern (see CST of FIG. 6) which will be discussed below. Each of the semiconductor chips 2200 may further include input/output pads (see 2210 of FIG. 2) electrically connected to the peripheral wiring lines 4110 of the first structure 4100.

The semiconductor chips 2200 of FIG. 3 or 4 may be electrically connected to each other through connection structures 2400 shaped like bonding wires. In some embodiments, in one semiconductor package including the semiconductor chips 2200 of FIG. 3 or 4, the semiconductor chips 2200 may be electrically connected to each other through connection structures 3265 or 4265 including through electrodes such as through silicon vias (TSV).

The first structure 3100 of FIG. 3 and the first structure 4100 of FIG. 4 may correspond to a peripheral circuit structure which will be discussed in the following embodiments, and the second structure 3200 of FIG. 3 and the second structure 4200 of FIG. 4 may correspond to a cell array structure which will be discussed in the following embodiments.

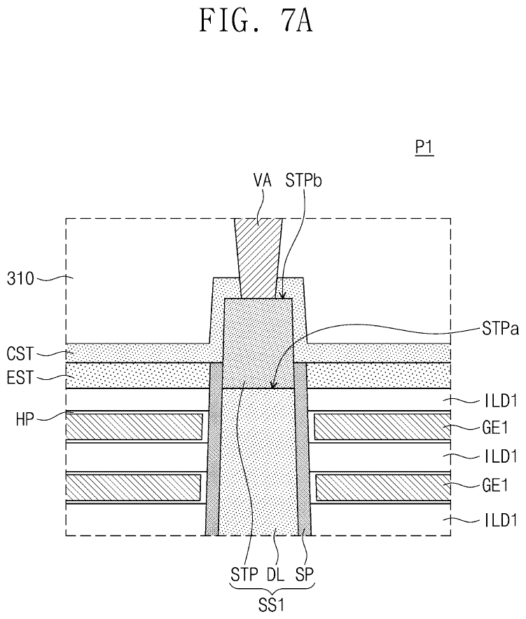

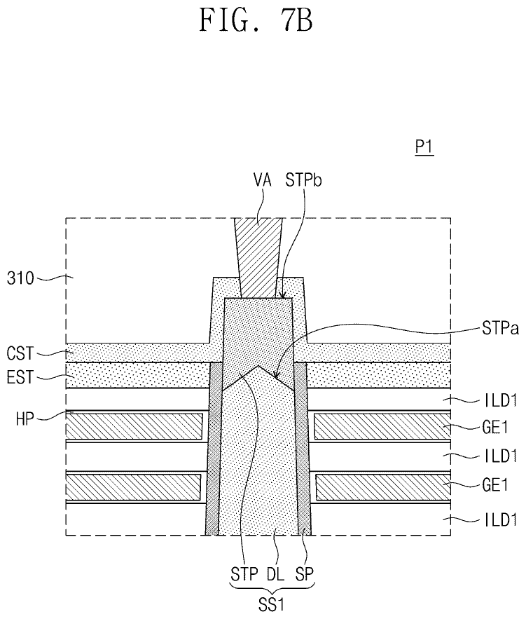

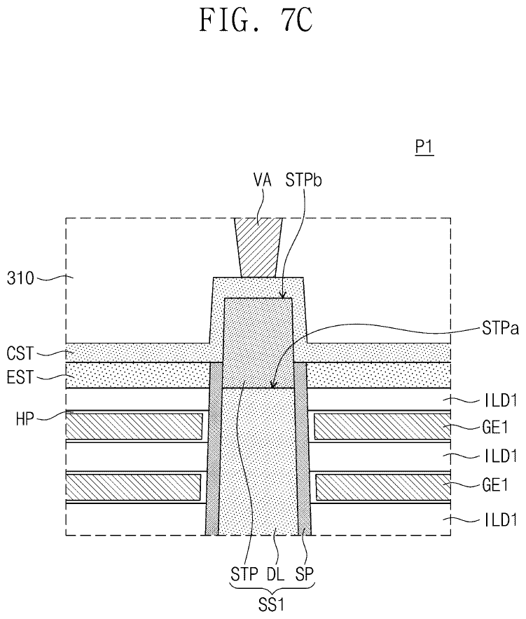

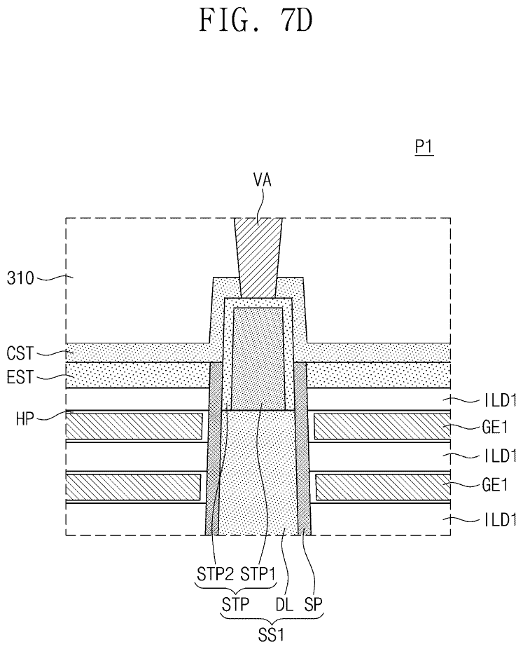

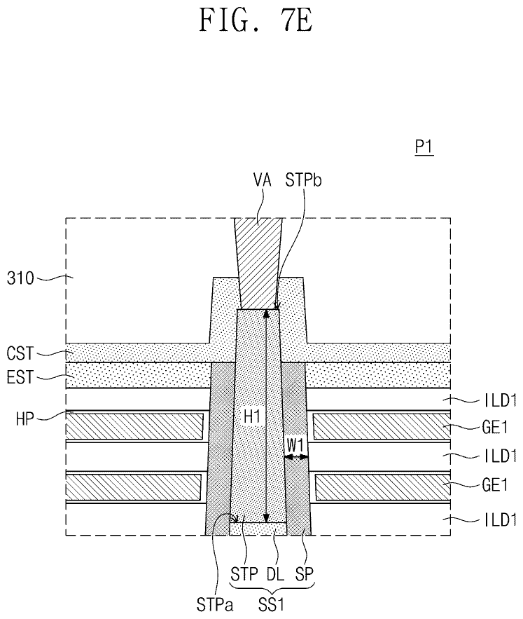

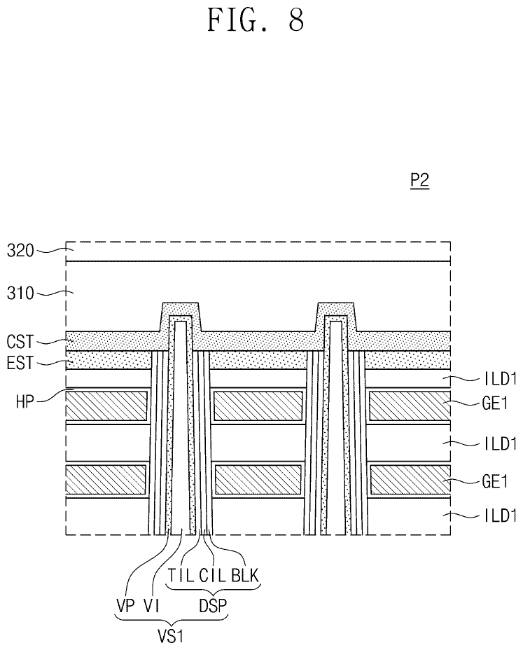

FIG. 5 illustrates a plan view showing a semiconductor device according to some embodiments of inventive concepts. FIG. 6A illustrates a cross-sectional view taken along line A-A′ of FIG. 5, showing a semiconductor device according to some embodiments of inventive concepts. FIG. 6B illustrates a cross-sectional view taken along line B-B′ of FIG. 5, showing a semiconductor device according to some embodiments of inventive concepts. FIG. 7A illustrates an enlarged view showing section P1 of FIG. 6A. FIG. 8 illustrates an enlarged view showing section P2 of FIG. 6A.

Referring to FIGS. 5, 6A, and 6B, a semiconductor device according to some embodiments of inventive concepts may include a peripheral circuit structure PS on a semiconductor substrate 200 and a cell array structure CS on the peripheral circuit structure PS.

According to some embodiments, as the cell array structure CS is bonded onto the peripheral circuit structure PS, it may be possible to increase a cell capacity per unit area of the semiconductor device according to inventive concepts. In addition, as the peripheral circuit structure PS and the cell array structure CS are manufactured separately and then bonded to each other, subsequently described peripheral circuits PTR may be limited and/or prevented from being damaged due to various heat treatment processes, and accordingly, it may be possible to improve reliability and electrical properties of the semiconductor device.

The peripheral circuit structure PS may include the semiconductor substrate 200, peripheral circuits PTR that control a memory cell array, and peripheral interlayer dielectric layers 210 and 220 that cover the peripheral circuits PTR. The peripheral circuits PTR may be integrated on a top surface of the semiconductor substrate 200. A surface dielectric layer 201 may be provided on a bottom surface of the semiconductor substrate 200.

The semiconductor substrate 200 may be, for example, a silicon substrate, a silicon-germanium substrate, a germanium substrate, or a monocrystalline epitaxial layer grown on a monocrystalline silicon substrate. The semiconductor substrate 200 may have the top surface that is parallel to a first direction D1 and a second direction that intersects the first direction D1 and is perpendicular to a third direction D3. The first, second, and third directions D1, D2, and D3 may be directions orthogonal to each other.

The peripheral circuits PTR may be row and column decoders, a page buffer, and a control circuit. For example, the peripheral circuits PTR may include NMOS and PMOS transistors. Peripheral circuit lines PLP may be electrically connected through peripheral contact plugs PCP to the peripheral circuits PTR.

The peripheral contact plugs PCP may each have a width in the first direction D1 or the second direction D2, and for example, the width may increase in the third direction D3. The peripheral contact plugs PCP and the peripheral circuit lines PLP may include a conductive material, such as metal.

The peripheral interlayer dielectric layers 210 and 220 may be provided on the top surface of the semiconductor substrate 200. On the semiconductor substrate 200, the peripheral interlayer dielectric layers 210 and 220 may cover the peripheral circuits PTR, the peripheral contact plugs PCP, and the peripheral circuit lines PLP. The peripheral contact plugs PCP and the peripheral circuit lines PLP may be electrically connected to the peripheral circuits PTR. The peripheral interlayer dielectric layers 210 and 220 may include one or more of a silicon oxide layer, a silicon nitride layer, a silicon oxynitride layer, and a low-k dielectric layer.

First bonding pads BP1 may be disposed in an uppermost peripheral interlayer dielectric layer 220. The uppermost peripheral interlayer dielectric layer 220 may not cover top surfaces of the first bonding pads BP1. A top surface of the uppermost peripheral interlayer dielectric layer 220 may be substantially coplanar with those of the first bonding pads BP1. The first bonding pads BP1 may be electrically connected to the peripheral circuits PTR through the peripheral circuit lines PLP and the peripheral contact plugs PCP.

The cell array structure CS may be provided on the peripheral circuit structure PS. The cell array structure CS of the semiconductor device may include a cell array region CAR and first and second connection regions CNR1 and CNR2, and the first connection region CNR1 may be positioned in the first direction D1 between the cell array region CAR and the second connection region CNR2.

The cell array structure CS may include a memory cell array including three-dimensionally arranged memory cells. The cell array structure CS may include a source conductive pattern CST, a stack structure ST, first and second vertical structures VS1 and VS2, bit lines BL, cell contact plugs CPLG, peripheral contact plugs PPLG, and input/output contact plugs IOPLG.

The stack structure ST of the cell array structure CS may be provided in plural. When viewed in plan as shown in FIG. 5, the plurality of stack structures ST may extend in the first direction D1 and may be spaced apart from each other in the second direction D2. For convenience of discussion, the following will focus on a single stack structure ST, and a description below may be identically applicable to other stack structures ST.

The stack structure ST may include conductive patterns GE1 and GE2 and interlayer dielectric layers ILD1 and ILD2 that are alternately stacked along the third direction D3 (or a vertical direction) perpendicular to the first and second directions D1 and D2.

An etch stop layer EST may be disposed on the stack structure ST. The etch stop layer EST may cover a top surface of the stack structure ST and may contact an uppermost first interlayer dielectric layer ILD1. For example, the etch stop layer EST may include polysilicon.

In some embodiments, the conductive patterns GE1 and GE2 may include first and second erase gate patterns adjacent to the source conductive pattern CST, a ground selection gate pattern on the second erase gate pattern, a plurality of cell gate pattern stacked on the ground selection gate pattern, and a string selection gate pattern on an uppermost cell gate pattern.

The conductive patterns GE1 and GE2 of the stack structure ST may be stacked to have an inverse stepwise structure on the first connection region CNR1. For example, the conductive patterns GE1 and GE2 may have their lengths that increase in the first direction D1 with increasing distance from the peripheral circuit structure PS.

Each of the conductive patterns GE1 and GE2 may have a pad part on the first connection region CNR1. The pad parts of the conductive patterns GE1 and GE2 may be located at positions that are horizontally and vertically different from each other. The cell contact plugs CPLG may be correspondingly coupled to the pad parts of the conductive patterns GE1 and GE2.

In some embodiments, the stack structure ST may include a first stack structure ST1 and a second stack structure ST2 on the first stack structure ST1. The first stack structure ST1 may include first interlayer dielectric layers ILD1 and first conductive patterns GE1 that are alternately stacked, and the second stack structure ST2 may include second interlayer dielectric layers ILD2 and second conductive patterns GE2 that are alternately stacked.

The second stack structure ST2 may be disposed between the first stack structure ST1 and the peripheral circuit structure PS. For example, the second stack structure ST2 may be provided on a bottom surface of a lowermost one of the first interlayer dielectric layers ILD1 included in the first structure ST1. Although an uppermost one of the second interlayer dielectric layers ILD2 included in the second stack structure ST2 is in contact with the lowermost one of the first interlayer dielectric layers ILD1 included in the first stack structure ST1, inventive concepts are not limited thereto, and a single-layered dielectric layer may be provided between an uppermost one of the second conductive patterns GE2 included in the second stack structure ST2 and a lowermost one of the first conductive patterns GE1 included in the first stack structure ST1.

A lowermost one of the second conductive patterns GE2 included in the second stack structure ST2 may have a minimum length in the first direction D1, and an uppermost one of the first conductive patterns GE1 included in the first stack structure ST1 may have a maximum length in the first direction D1.

The first and second conductive patterns GE1 and GE2 may include, for example, at least one selected from doped semiconductors (e.g., doped silicon), metals (e.g., tungsten, molybdenum, nickel, copper, or aluminum), conductive metal nitrides (e.g., titanium nitride or tantalum nitride), and transition metals (e.g., titanium or tantalum). The first and second interlayer dielectric layers ILD1 and ILD2 may include one or more of silicon oxide, silicon nitride, silicon oxynitride, and low-k dielectrics. For example, the first and second interlayer dielectric layers ILD1 and ILD2 may include high-density plasma (HDP) oxide or tetraethylorthosilicate (TEOS).

According to some embodiments, the semiconductor device may be a vertical NANF Flash memory device, and in this case, the first and second conductive patterns GE1 and GE2 of the semiconductor device may be used as the gate lower lines LL1 and LL2, the word lines WL, and the gate upper lines UL1 and UL2 discussed with reference to FIG. 1.

A planarized dielectric layer 110a and 110b may cover stepwise ends (or the pad parts) of the stack structure ST. The planarized dielectric layer 110a and 110b may have a substantially flat top surface. The planarized dielectric layer 110a and 110b may include a single dielectric layer or a plurality of stacked dielectric layers. For example, the planarized dielectric layer 110a and 110b may include a first planarized dielectric layer 110a that covers a stepwise structure of the first stack structure ST1 and a second planarized dielectric layer 110b that covers a stepwise structure of the second stack structure ST2. The planarized dielectric layer 110a and 110b may have substantially flat top and bottom surfaces. The top surface of the planarized dielectric layer 110a and 110b may be substantially coplanar with the etch stop layer EST on the stack structure ST, and the bottom surface of the planarized dielectric layer 110a and 110b may be substantially coplanar with a lowermost interlayer dielectric layer ILD2 of the stack structure ST.

The source conductive pattern CST may be disposed on an uppermost first interlayer dielectric layers ILD1 of the first stack structure ST1. The source conductive pattern CST may correspond to one of the source structure 3205 of FIG. 3 and the source structure 4205 of FIG. 4. The source conductive pattern CST may have a uniform thickness. The source conductive pattern CST may extend in the first direction D1 and the second direction D2 on the cell array region CAR and the first connection region CNR1. When viewed in the first direction D1, the source conductive pattern CST may have a length greater than that of the uppermost first conductive pattern GE1 of the first stack structure ST1.

The source conductive pattern CST may cover the first vertical structures VS1 and separation structures SS1 and SS2 which will be discussed below. For example, the first vertical structures VS1 and the separation structures SS1 and SS2 may have their upper portions that protrude from the stack structure ST, and the source conductive pattern CST may have a uniform or a substantially uniform thickness that covers the protruding upper portions.

In some embodiments, the source conductive pattern CST may include at least one selected from polysilicon, doped semiconductors (e.g., doped silicon), metals (e.g., tungsten, copper, or aluminum), conductive metal nitrides (e.g., titanium nitride or tantalum nitride), and transition metals (e.g., titanium or tantalum).

On the second connection region CNR2, upper conductive patterns CP may be disposed on the top surface of the first planarized dielectric layer 110a and may be located at substantially the same level as that of the source conductive pattern CST. The upper conductive pattern CP may include the same conductive material as that of the source conductive pattern CST. The input/output contact plugs IOPLG may be connected through upper vias VA to input/output pads IOPAD.

On the cell array region CAR, a plurality of first vertical structures VS1 may penetrate the stack structure ST to come into connection with the source conductive pattern CST. When viewed in plan, the first vertical structures VS1 may be arranged in a straight or zigzag fashion along one direction. The second vertical structures VS2 may penetrate the stack structure ST on the first connection region CNR1.

On the first connection region CNR1, the second vertical structures VS2 may penetrate end part (or the pad parts) of the first and second conductive patterns GE1 and GE2. The second vertical structures VS2 may have substantially the same structure as that of the first vertical structures VS1, and may include the same material as that of the first vertical structures VS1.

The second vertical structures VS2 may differ from the first vertical structures VS1 in terms of planar shape and size. The second vertical structures VS2 may have their top surfaces each having a circular shape, an oval shape, a bar shape, or any other suitable shapes. The second vertical structures VS2 may be disposed to surround the cell contact plug CPLG. When the top surfaces of the second vertical structures VS2 have oval shapes, major axes of the second vertical structures VS2 may be disposed in different directions on the pad part of each of the first and second conductive patterns GE1 and GE2. A plurality of second vertical structures VS2 may be provided between neighboring cell contact plugs CPLG.

In some embodiments, each of the first vertical structures VS1 may be provided in a vertical channel hole that penetrates the stack structure ST. The vertical channel hole may include a first vertical channel hole that penetrates the first stack structure ST1, and may also include a second vertical channel hole that penetrates the second stack structure ST2 and is connected to the first vertical channel hole.

Each of the first vertical structures VS1 may include a first vertical extension in the first vertical channel hole and a second vertical extension in the second vertical channel hole. The first vertical extension and the second vertical extension may be a single structure that extends continuously with no boundary. The first vertical extension may have a sidewall whose slope is uniform from lower to upper portions thereof. Likewise, the second vertical extension may have a sidewall whose slope is uniform from lower to upper portions thereof. For example, each of the first and second vertical extensions may have a width in the first direction D1 or the second direction D2 that decreases with increasing distance from the semiconductor substrate 200. The first vertical extension and the second vertical extension may have different diameters at their connection portion. A step difference may be provided at the connection portion where the first vertical extension and the second vertical extension are connected to each other.

Inventive concepts, however, are not limited thereto, and differently from that shown, each of the first vertical structures VS1 may have three or more vertical extensions having step differences at two or more boundaries. Alternatively, each of the first vertical structure VS1 may have a flat sidewall with no step difference.

Referring to FIGS. 5, 6A, 6B, and 7A, a first interlayer dielectric layer 120 may be disposed below the planarized dielectric layer 110a and 110b and the stack structure ST. The first interlayer dielectric layer 120 may cover bottom surfaces of the first vertical structures VS1.

First, second, and third separation structures SS1, SS2, and SS3 may penetrate the first interlayer dielectric layer 120, the planarized dielectric layer 110a and 110b, and the stack structure ST. Each of the first, second, and third separation structures SS1, SS2, and SS3 may include a stop pattern STP, a dielectric pattern DL, and a spacer SP.

The dielectric pattern DL may be disposed on a second interlayer dielectric layer 130, and the stop pattern STP may be disposed on the dielectric pattern DL. The dielectric pattern DL and the stop pattern STP may be disposed along a vertical direction (or the third direction D3), and an upper portion of the stop pattern STP may protrude from the etch stop layer EST. For example, a top surface STPb of the stop pattern STP may be located at a higher level than that of a top surface of the etch stop layer EST, and the upper portion of the stop pattern STP may be covered with the source conductive pattern CST.

The spacer SP may surround an outer lateral surface of the dielectric pattern DL and an outer lateral surface of the stop pattern STP. A top surface of the dielectric pattern DL may be in contact with a bottom surface STPa of the stop pattern STP, and the spacer SP may be disposed between the dielectric pattern DL and the stack structure ST and between the stop pattern STP and the stack structure ST. A top surface of the spacer SP may be coplanar with that of the etch stop layer EST. For example, the stop pattern STP may include at least one selected from amorphous silicon, polysilicon, and metal, and the dielectric pattern DL may include at least one selected from silicon oxide, silicon nitride, and silicon oxynitride. The spacer SP may include silicon oxide or silicon oxynitride.

The stop pattern STP may be disposed in only a portion of each of the separation structures SS1, SS2, and SS3. For example, the stop pattern STP may be positioned on an upper portion of each of the separation structures SS1, SS2, and SS3. The stop pattern STP may have the bottom surface STPa and the top surface STPb that are opposite to each other in the third direction D3, and the top surface STPb of the stop pattern STP may be adjacent to the source conductive pattern CST. The bottom surface STPa of the stop pattern STP may be located at a higher level than that of a bottom surface of the stack structure ST. A vertical length of the stop pattern STP may be less than that of the dielectric pattern DL. The vertical length of each of the stop pattern STP and the dielectric pattern DL may indicate a length in the third direction D3.

When the stop pattern STP is positioned on an upper portion of each of the separation structures SS1, SS2, and SS3, the stop pattern STP may serve as a stopper in a procedure where an upper dielectric layer 310 is patterned to form the upper via VA as discussed below. For example, the stop pattern STP may serve to limit and/or prevent the dielectric patterns DL of the separation structures SS1, SS2, and SS3 from being over-etched when holes are formed to penetrate the upper dielectric layer 310 for forming the upper vias VA.

According to some embodiments, the bottom surface STPa of the stop pattern STP may be located at a higher level than that of the conductive patterns GE1 and GE2 and that of a top surface of the conductive pattern GE1, which is most adjacent to the source conductive pattern CST, among the conductive patterns GE1 and GE2. A sufficient interval may thus be secured between the stop pattern STP and the conductive patterns GE1 and GE2, and even when the stop pattern STP includes metal, the stop pattern STP and the conductive patterns GE1 and GE2 may be less electrically affected by each other.

Amorphous silicon or polysilicon may be relatively more vulnerable to heat-induced deformation than other dielectric materials, and when heat is applied to the separation structures SS1, SS2, and SS3 are filled with only amorphous silicon or polysilicon, a large thermal deformation may occur to cause a warpage phenomenon. In contrast, according to some embodiments of inventive concepts, the stop pattern STP may be disposed in only a portion of each of the separation structures SS1, SS2, and SS3, and thus even when the stop pattern STP includes amorphous silicon or polysilicon, a warpage phenomenon may be at least partially limited and/or prevented.

The first separation structures SS1 may extend along the first direction D1 from the cell array region CAR toward the first connection region CNR1, and may be spaced apart from each other in the second direction D2 that intersects the first direction D1. In some embodiments, the stack structure ST may be disposed between the first separation structures SS1 that are adjacent to each other in the second direction D2.

The second separation structure SS2 may penetrate the stack structure ST on the cell array region CAR. The second separation structure SS2 may be disposed between the first separation structures SS1. When viewed in the first direction D1, the second separation structure SS2 may have a length less than that of the first separation structure SS1. Alternatively, a plurality of second separation structures SS2 may be provided between the first separation structures SS1.

On the first connection region CNR1, the third separation structures SS3 may penetrate the planarized dielectric layer 110a and 110b and the stack structure ST, while being spaced apart in the first direction D1 from the first and second separation structures SS1 and SS2. The third separation structures SS3 may extend along the first direction D1. The third separation structures SS3 may be spaced apart from each other in the first direction D1 and the second direction D2.

A bit-line conductive pad may be formed on a lower end of the first vertical structure VS1, and an upper bit-line contact plug BCTa may penetrate the first and second interlayer dielectric layers 120 and 130 to come into contact with the bit-line conductive pad. The bit-line conductive pad may include an impurity-undoped semiconductor material, an impurity-doped semiconductor material, or a conductive material. A lower bit-line contact plug BCTb may penetrate a third interlayer dielectric layer 140 to be coupled to the upper bit-line contact plug BCTa.

On the first connection region CNR1, the cell contact plugs CPLG may penetrate the first, second, and third interlayer dielectric layers 120, 130, and 140 and the planarized dielectric layer 110a and 110b to be correspondingly coupled to the pad parts of the first and second conductive patterns GE1 and GE2. The cell contact plugs CPLG may have their vertical lengths that decrease with decreasing distance from the cell array region CAR. The cell contact plugs CPLG may have their top surfaces substantially coplanar with each other.

On the second connection region CNR2, the peripheral contact plugs PPLG and the input/output contact plugs IOPLG may penetrate the first, second, and third interlayer dielectric layers 120, 130, and 140 and the planarized dielectric layer 110a and 110b to be coupled to the upper conductive patterns CP.

Each of the cell, peripheral, and input/output contact plugs CPLG, PPLG, and IOPLG may include a barrier metal layer including conductive metal nitride (e.g., titanium nitride or tantalum nitride) and a metal layer including metal (e.g., tungsten, titanium, or tantalum).

On the cell array region CAR, the bit lines BL may be disposed on the third interlayer dielectric layer 140. The bit lines BL may extend in the second direction D2, while running across the stack structure ST. The bit lines BL may be electrically connected to the first vertical structures VS1 through the upper and lower bit-line contact plugs BCTa and BCTb.

First lower conductive lines LCLa may be disposed below the third interlayer dielectric layer 140 on the first connection region CNR1, thereby being coupled to the cell contact plugs CPLG.

Second lower conductive lines LCLb may be disposed below the third interlayer dielectric layer 140 on the second connection region CNR2, thereby being coupled to the peripheral and input/output contact plugs PPLG and IOPLG.

A fourth interlayer dielectric layer 150 may be disposed below the third interlayer dielectric layer 140, and the bit lines BL and the first and second lower conductive lines LCLa and LCLb may be disposed in the fourth interlayer dielectric layer 150.

A fifth interlayer dielectric layer 160 may be disposed below the fourth interlayer dielectric layer 150, and first and second upper conductive lines UCLa and UCLb may be disposed in the fifth interlayer dielectric layer 160. On the cell array region CAR, the first upper conductive lines UCLa may be electrically connected to the bit lines BL. On the first and second connection regions CNR1 and CNR2, the second upper conductive lines UCLb may be electrically connected to the first and second lower conductive lines LCLa and LCLb.

The first and second lower conductive lines LCLa and LCLb and the first and second upper conductive lines UCLa and UCLb may include at least one selected from metals (e.g., tungsten, copper, or aluminum), conductive metal nitrides (e.g., titanium nitride or tantalum nitride), and transition metals (e.g., titanium or tantalum). For example, the first and second lower conductive lines LCLa and LCLb may be formed of tungsten whose electrical resistivity is relatively higher, and the first and second upper conductive lines UCLa and UCLb may be formed of copper whose electrical resistivity is relatively lower.

A sixth interlayer dielectric layer 170 may be disposed below the fifth interlayer dielectric layer 160, and second bonding pads BP2 may be disposed in the sixth interlayer dielectric layer 170. The second bonding pads BP2 may be electrically connected to the first and second upper conductive lines UCLa and UCLb. The second bonding pads BP2 may be formed of aluminum, copper, or tungsten.

A bonding method may be employed to electrically and physically connect the second bonding pads BP2 to the first bonding pads BP1. For example, the second bonding pads BP2 may be in direct contact with the first bonding pads BP1.

The second bonding pads BP2 may include the same metallic material as that of the first bonding pads BP1. The second bonding pads BP2 may have substantially the same shape, width, and area as those of the first bonding pads BP1.

The upper dielectric layer 310 may cover the source conductive pattern CST and the upper conductive patterns CP. The upper vias VA penetrating the upper dielectric layer 310 may be disposed on the source conductive pattern CST and the upper conductive patterns CP. The upper vias VA may be disposed on the source conductive pattern CST, or may penetrate the source conductive pattern CST, or may penetrate the source conductive pattern CST to come into contact with the top surfaces STPb of the stop patterns STP of the separation structures SS1, SS2, and SS3.

The upper dielectric layer 310 may be provided thereon with wiring patterns PAD and the input/output pads IOPAD. A capping dielectric layer 320 may be disposed on the upper dielectric layer 310, and the capping dielectric layer 320 may cover the wiring patterns PAD and the input/output pads IOPAD.

The capping dielectric layer 320 and a passivation layer 340 may be sequentially formed on a front surface of the upper dielectric layer 310. The capping dielectric layer 320 may include, for example, a silicon nitride layer or a silicon oxynitride layer. The passivation layer 340 may include a polyimide-based material, such as photosensitive polyimide (PSPI).

The capping dielectric layer 320 and the passivation layer 340 may have a pad opening OP that expose a portion of the input/output pad IOPAD.

FIGS. 7B to 7E illustrate enlarged cross-sectional views showing section P1 according to some embodiments of inventive concepts. For brevity of explanation, a detailed description of technical features the same as those of the semiconductor device discussed above may be omitted, and a difference thereof will be described.

Referring to FIGS. 5, 6A, and 7B, the stop pattern STP and the dielectric pattern DL may be changed in their shape. For example, the bottom surface STPa of the stop pattern STP may have a recess, and the recess may be upwardly recessed. The top surface of the dielectric pattern DL may be in contact with the recess. For example, the top surface of the dielectric pattern DL may have a convexly protruding shape.

Referring to FIGS. 5, 6A, and 7C, the stop pattern STP may be disposed spaced apart from, without being in contact with, the upper via VA. For example, the stop pattern STP and the upper via VA may be spaced apart from each other across the source conductive pattern CST.

Referring to FIGS. 5, 6A, and 7D, the stop pattern STP may include a first stop pattern STP1 and a second stop pattern STP2. The first stop pattern STP1 may be disposed on the dielectric pattern DL, and on the dielectric pattern DL, the second stop pattern STP2 may be interposed between the first stop pattern STP1 and the source conductive pattern CST. The second stop pattern STP2 may surround top and lateral surfaces of the first stop pattern STP1.

The second stop pattern STP2 may include a low-k dielectric material, and may have a dielectric constant less than that of the first stop pattern STP1. Thus, the second stop pattern STP2 having a low dielectric constant may surround the top and lateral surfaces of the first stop pattern STP1, and there may be a reduction in electrical interference between the first conductive patterns GE1 and the first stop pattern STP1.

Referring to FIGS. 5, 6A, and 7E, the spacer SP may have a relatively large width W1. In this case, the spacer SP may secure a distance between the stop pattern STP and the first conductive patterns GE1, and thus the bottom surface STPa of the stop pattern STP may be located at a lower level than that of a bottom surface of at least one of the first conductive patterns GE1. Thus, the stop pattern STP may have a relatively large height H1. The width W1 of the spacer SP may indicate a thickness in a direction (e.g., the first direction D1 or the second direction D2) parallel to the top surface of the stack structure ST, and the height H1 of the stop pattern STP may indicate a distance in a vertical direction (e.g., the third direction D3) from the top surface STPb of the stop pattern STP to the bottom surface STPa of the stop pattern STP.

Referring to FIGS. 5, 6A, and 8, the first vertical structures VS1 may extend in the third direction D3 perpendicular to the top surface of the semiconductor substrate 200, thereby penetrating the stack structure ST and connecting with the source conductive pattern CST.

Each of the first vertical structures VS1 may include a vertical channel pattern VP, a data storage pattern DSP, and a vertical dielectric pattern VI.

For example, the vertical channel pattern VP may have a macaroni shape or a pipe shape whose top and bottom ends are closed. The vertical channel pattern VP may have an inner sidewall that defines an internal space and an outer sidewall adjacent to the stack structure ST. The vertical channel pattern VP may surround an outer sidewall of the vertical dielectric pattern VI, and a portion of the vertical channel pattern VI may be disposed between the source conductive pattern CST and the vertical dielectric pattern VI.

The vertical channel pattern VP may include a semiconductor material, such as silicon (Si), germanium (Ge), or a mixture thereof. The vertical channel pattern VP including the semiconductor material may be used as channels of the upper transistors UT1 and UT2, of the memory cell transistors MCT, and of the lower transistors LT1 and LT2, all of which transistors are discussed with reference to FIG. 1.

The vertical channel pattern VP may be connected to the source conductive pattern CST. For example, the vertical channel pattern VP may have an upper portion that protrudes from the etch stop layer EST, and the protruding upper portion of the vertical channel pattern VP may be covered with the source conductive pattern CST. A top surface of the vertical channel pattern VP may be located at a higher level than that of the top surface of the etch stop layer EST.

The data storage pattern DSP may extend in the third direction D3 and surround the outer sidewall of the vertical channel pattern VP. For example, a top surface of the data storage pattern DSP may be located at a lower level than that of the top surface of the vertical channel pattern VP, and may be coplanar with the top surface of the etch stop layer EST. The data storage pattern DSP may have a macaroni or a pipe shape whose top end is opened. The data storage pattern DSP may be formed of a single thin layer or a plurality of thin layers. In some embodiments of inventive concepts, the data storage pattern DSP may include a tunnel dielectric layer TIL, a charge storage layer CIL, and a blocking dielectric layer BLK, which constitute a data storage layer of a NAND Flash memory device. For example, the charge storage layer CIL may be a trap dielectric layer, a floating gate electrode, or a dielectric layer including conductive nano-dots.

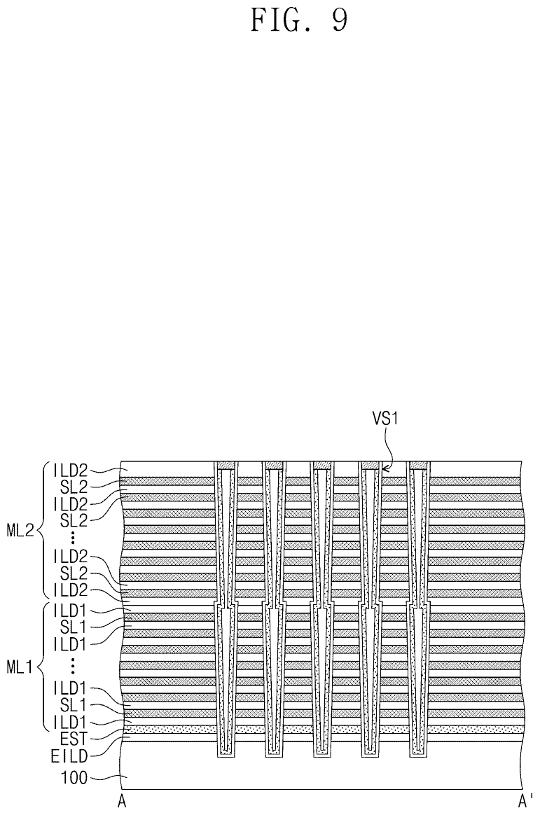

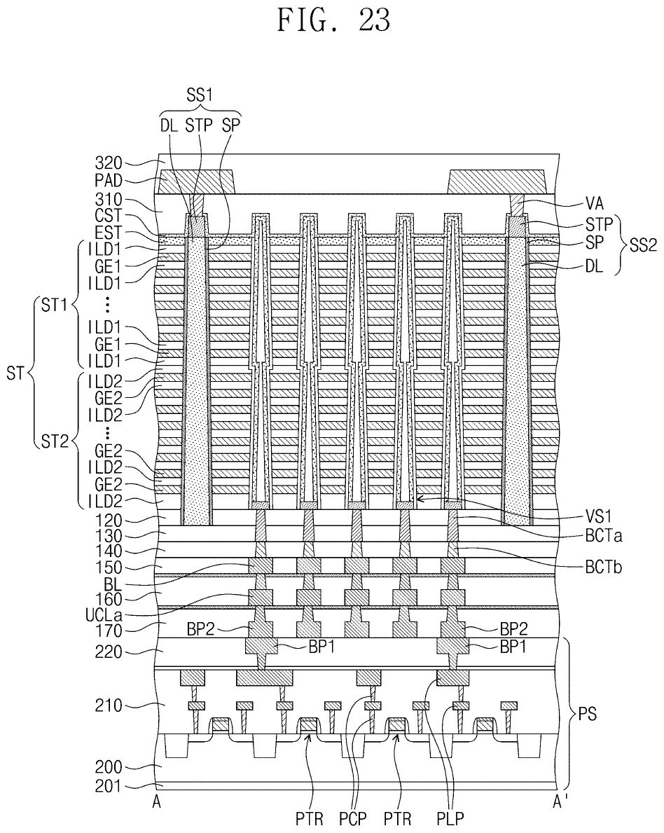

FIGS. 9 to 11, 12A, 12B, 12C, and 13 to 23 illustrate cross-sectional views taken along line A-A′ of FIG. 5, showing a method of fabricating a semiconductor device according to some embodiments of inventive concepts.

Referring to FIGS. 5 and 9, a lowermost dielectric layer EILD, an etch stop layer EST, and a first mold structure ML1 may be formed on a first substrate 100.

The formation of the first mold structure ML1 may include forming a first thin-layer structure (not shown) in which first interlayer dielectric layers ILD1 and first sacrificial layers SL1 are vertically alternately stacked, and repeatedly performing a patterning process on the first thin-layer structure. Thus, the first mold structure ML1 may have a stepwise structure on a first connection region CNR1.

The lowermost dielectric layer EILD, the etch stop layer EST, the first interlayer dielectric layers ILD1, and the first sacrificial layers SL1 may be deposited by using one of a thermal chemical vapor deposition (CVD), plasma enhanced CVD, physical CVD process, and atomic layer deposition (ALD).

The etch stop layer EST may be formed of a different material from that of the lowermost dielectric layer EILD, and unlike the lowermost dielectric layers EILD, the etch stop layer EST may be resistant to etching. For example, the etch stop layer EST may be formed of polysilicon, and the lowermost dielectric layer EILD may be formed of silicon oxide.

In the first mold structure ML1, the first sacrificial layers SL1 may be formed of a material that can be etched with an etch selectivity with respect to the first interlayer dielectric layers ILD1. For example, the first sacrificial layers SL1 may be formed of a dielectric material different from that of the first interlayer dielectric layers ILD1. For example, the first sacrificial layers SL1 may be formed of a silicon nitride layer, and the first interlayer dielectric layers ILD1 may be formed of a silicon oxide layer.

After the formation of the first mold structure ML1, a first planarized dielectric layer 110a may be formed to cover the stepwise structure of the first mold structure ML1.

A second mold structure ML2 may be formed on the first mold structure ML1. According to some embodiments, before the formation of the second mold structure ML2, vertical sacrificial patterns (not shown) may be formed to penetrate the first mold structure ML1.

The formation of the second mold structure ML2 may be substantially the same as the formation of the first mold structure ML1 discussed above. For example, the formation of the second mold structure ML2 may include forming on the first mold structure ML1 a second thin-layer structure (not shown) in which second interlayer dielectric layers ILD2 and second sacrificial layers SL2 are vertically alternately stacked, and repeatedly performing a patterning process on the second thin-layer structure. Therefore, the second mold structure ML2 may have a stepwise structure on the first connection region CNR1.

The second sacrificial layers SL2 may include the same material as that of the first sacrificial layers SL1 and may have substantially the same thickness as that of the first sacrificial layers SL1. The second sacrificial layers SL2 may be formed of a dielectric material different from that of the second interlayer dielectric layers ILD2. The second sacrificial layers SL2 may be formed of the same material as that of the first sacrificial layers SL1. For example, the second sacrificial layers SL2 may be formed of a silicon nitride layer, and the second interlayer dielectric layers ILD2 may be formed of a silicon oxide layer.

After the formation of the second mold structure ML2, a second planarized dielectric layer 110b may be formed to cover the stepwise structure of the second mold structure ML2. The first planarized dielectric layer 110a and the second planarized dielectric layer 110b may constitute a planarized dielectric layer 110a and 110b.

Vertical channel holes may be formed to penetrate the first and second mold structures ML1 and ML2 and to expose the first substrate 100. When vertical sacrificial patterns (not shown) are formed in the first mold structure ML1, the formation of the vertical channel holes may include removing the vertical sacrificial patterns to expose the first substrate 100.

When the vertical channel holes are formed, on the first connection region CNR1, dummy channel holes may be formed to penetrate the planarized dielectric layer 110a and 110b and portions of the first and second mold structures ML1 and ML2.

The formation of the vertical channel holes may include forming a hardmask pattern on the second mold structure ML2 and using the hardmask pattern as an etching mask to anisotropically etch the first and second mold structures ML1 and ML2. The anisotropic etching process for forming the vertical channel holes may a top surface of the first substrate 100, and the top surface of the first substrate 100 exposed through the vertical channel holes may be recessed to a certain depth. In addition, in the anisotropic etching process for forming the vertical channel holes, the recess depth of the first substrate 100 may be changed depending on positions of the vertical channel holes.

Afterwards, first vertical structures VS1 may be formed in the vertical channel holes on a cell array region CAR, and second vertical structures VS2 may be formed in the dummy channel holes on the first connection region CNR1.

The formation of the first and second vertical channel structures VS1 and VS2 may include sequentially depositing a data storage layer and a vertical channel layer in the vertical channel holes, and etching and planarizing the data storage layer and the vertical channel layer.

A chemical vapor deposition (CVD) process or an atomic layer deposition (ALD) process may be used to deposit the data storage layer having a uniform thickness on bottom surfaces and inner sidewalls of the vertical channel holes. The data storage layer may include a blocking dielectric layer, a charge storage layer, and a tunneling dielectric layer that are sequentially stacked in the vertical channel holes. A chemical vapor deposition (CVD) process or an atomic layer deposition (ALD) process may be used to deposit the vertical channel layer having a uniform thickness on the data storage layer. After the formation of the data storage layer and the vertical channel layer, the vertical channel holes may be filled with a gap-fill dielectric layer. Therefore, as discussed above with reference to FIG. 8, a data storage pattern DSP, a vertical channel pattern VP, and a vertical dielectric pattern VI may be formed in each vertical channel hole.

After that, bit-line conductive pads may be formed on top ends of the vertical channel patterns VP. The bit-line conductive pads may be impurity-doped regions or may be formed of a conductive material. The bit-line conductive pads may have their top surfaces coplanar with that of an uppermost second interlayer dielectric layer ILD2.

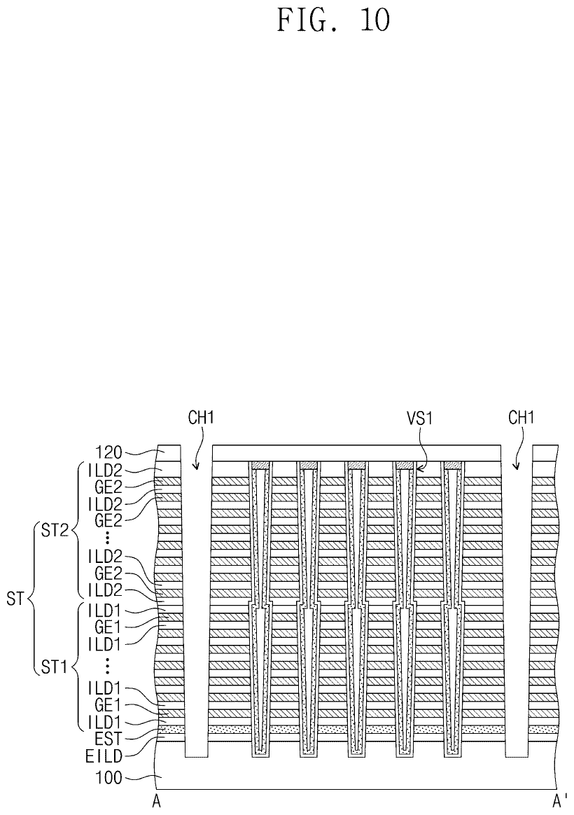

Referring to FIGS. 5 and 10, a first interlayer dielectric layer 120 may be formed on the second planarized dielectric layer 110b, covering top surfaces of the first and second vertical structures VS1 and VS2.

The first and second mold structures ML1 and ML2 may be patterned to form a first trench CH1. The trench CH1 may penetrate the first and second mold structures ML1 and ML2, the etch stop layer EST, and the lowermost dielectric layer EILD, and may additionally penetrate a portion of the first substrate 100.

A process may be performed to replace the first and second sacrificial layers SL1 and SL2 of the first and second mold structures ML1 and ML2 with first and second conductive patterns GE1 and GE2. Thus, a stack structure ST may be formed on the first substrate 100.

The process, in which the first and second sacrificial layers SL1 and SL2 are replaced with the first and second conductive patterns GE1 and GE2, may include isotropically etching the first and second sacrificial layers SL1 and SL2 by using an etch recipe having an etch selectivity with respect to the first and second interlayer dielectric layers ILD1 and ILD2, the first and second vertical structures VS1 and VS2, and the first substrate 100.

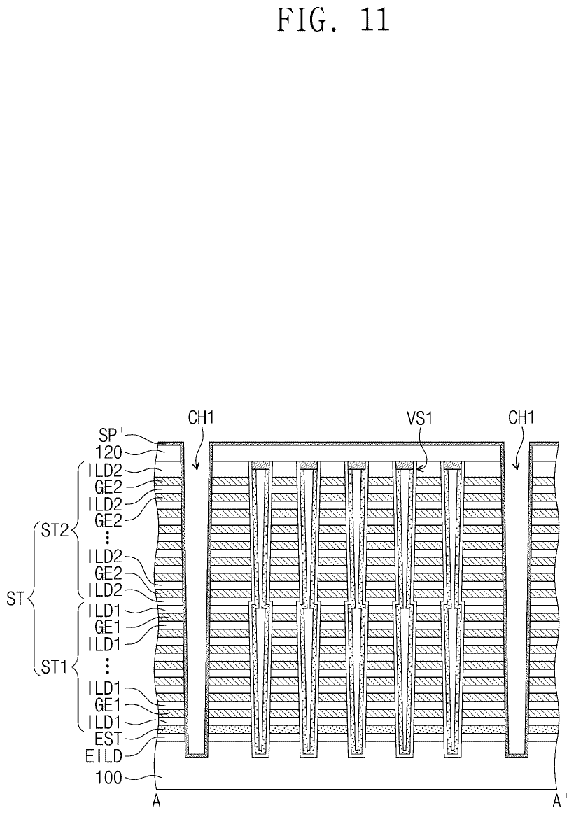

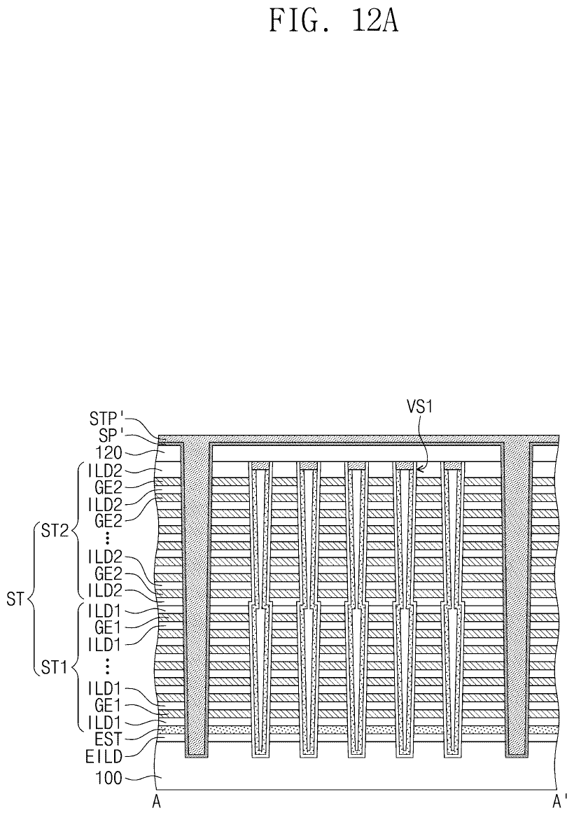

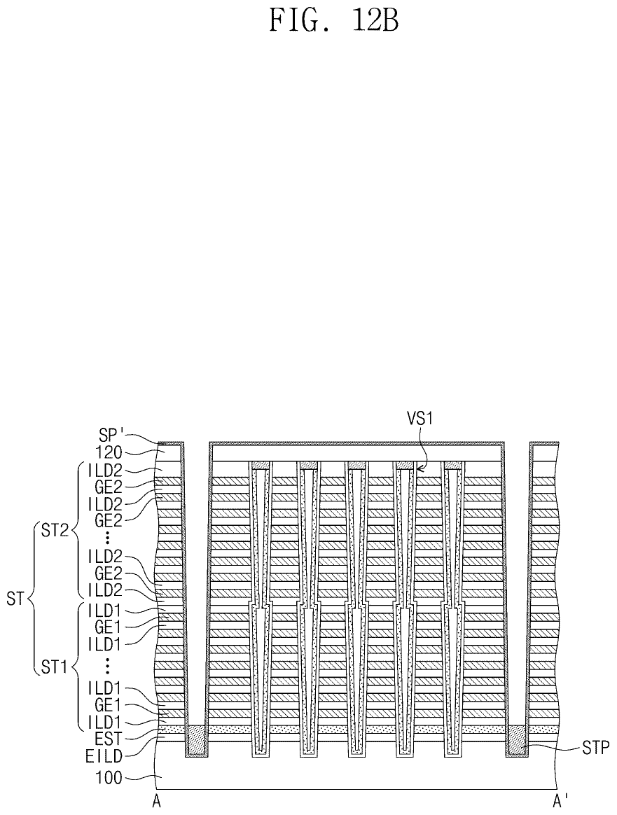

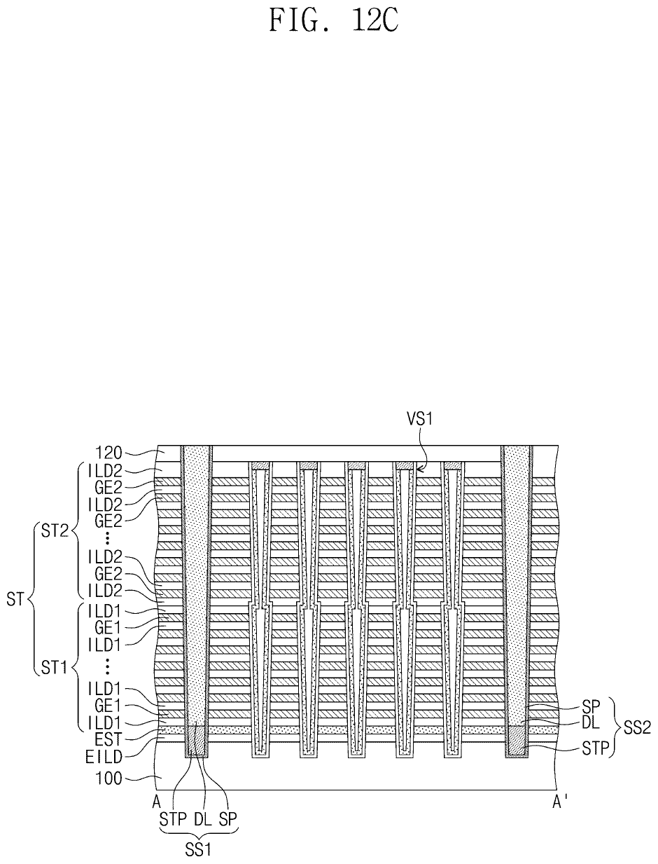

Referring to FIGS. 11 and 12A to 12C, separation structures SS1 and SS2 may be formed in the trenches CH1.

For example, referring to FIGS. 5 and 11, a spacer layer SP′ may be formed on the first interlayer dielectric layer 120 and the trench CH1, and may conformally cover a top surface of the first interlayer dielectric layer 120 and a bottom surface and an inner wall of the trench CH1. For example, the spacer layer SP′ may be formed by using chemical vapor deposition (CVD) or atomic layer deposition (ALD).

Referring to FIG. 12A, a stop layer STP′ may be formed on the spacer layer SP′. The stop layer STP′ may fill the trench CH1. For example, a chemical vapor deposition (CVD) process may be used to fill the trench CH1 with the stop layer STP′. The stop layer STP′ may include at least one selected from amorphous silicon, polysilicon, and metal.

Referring to FIG. 12B, a portion of the stop layer STP′ may be etched to form a stop pattern STP. For example, the stop layer STP′ may be etch-backed to leave a portion of the stop layer STP′ while removing a remaining portion of the stop layer STP′, such that the stop pattern STP may be formed in a lower portion of the trench CH1. A top surface of the stop pattern STP may be located at a lower level than that of a bottom surface of a lowermost one of the first conductive patterns GE1.

Referring to FIG. 12C, a dielectric pattern DL may fill the trench CH1 in which the stop pattern STP is formed. For example, the dielectric pattern DL may be formed by using a chemical vapor deposition (CVD) to form a dielectric layer that fills the trench CH1 in which the stop pattern STP is formed, and then performing a planarization process on the dielectric layer to expose the first interlayer dielectric layer 120. The planarization process may remove a portion of the spacer layer SP′ on the first interlayer dielectric layer 120 and may form a spacer SP. The planarization process may include, for example, a chemical mechanical polishing (CMP) process or an etch-back process.

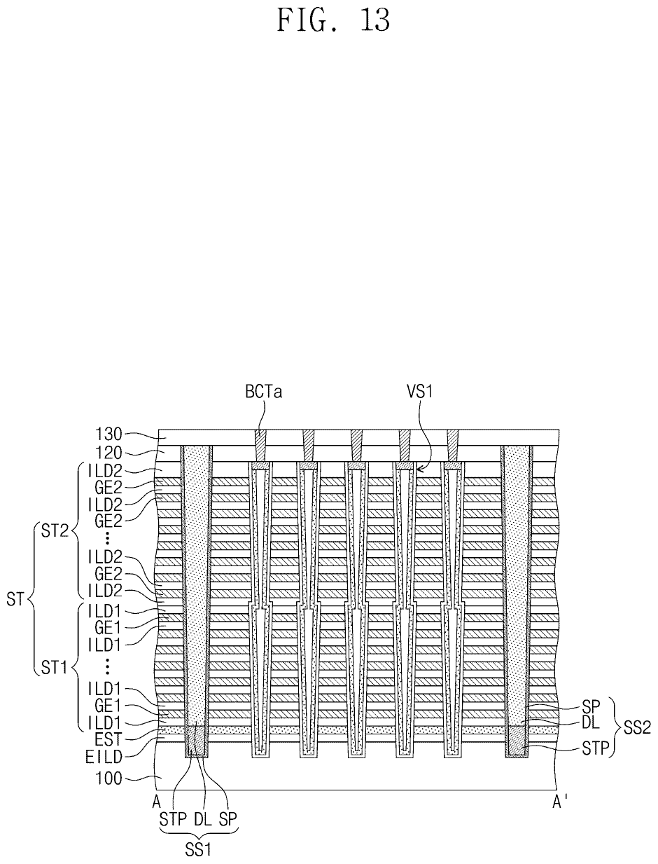

Referring to FIGS. 5 and 13, after the formation of the stack structure ST and the separation structures SS1 and SS2, a second interlayer dielectric layer 130 may be formed on the first interlayer dielectric layer 120. After that, upper bit-line contact plugs BCTa may be formed to penetrate the first and second interlayer dielectric layers 120 and 130 to be coupled to the first vertical structures VS1. The upper bit-line contact plugs BCTa may be in contact with the bit-line conductive pads of the first vertical structures VS1. The bit-line conductive pads may be formed of an impurity-undoped semiconductor material, an impurity-doped semiconductor material, or a conductive material.

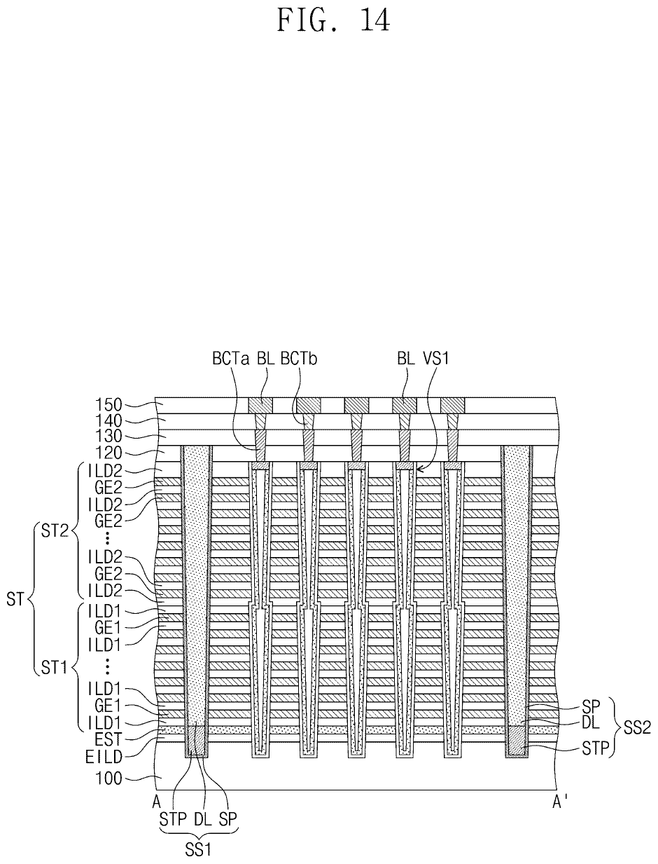

Referring to FIGS. 5 and 14, a third interlayer dielectric layer 140 may be formed on the second interlayer dielectric layer 130, and lower bit-line contact plugs BCTb may be formed to penetrate the third interlayer dielectric layer 140 to be coupled to the upper bit-line contact plugs BCTa. In addition, on the first and second connection regions CNR1 and CNR2, there may be formed cell contact plugs CPLG, peripheral contact plugs PPLG, and an input/output contact plug IOPLG. On the second connection region CNR2, the peripheral contact plugs PPLG and the input/output contact plug IOPLG may be formed by forming contact holes that penetrate the first, second, and third interlayer dielectric layers 120, 130, and 140 and the planarized dielectric layer 110a and 110b to expose the first substrate 100, and then filling the contact holes with a conductive materials.

Bit lines BL may be formed on the third interlayer dielectric layer 140. The bit lines BL may be connected to the upper and lower bit-line contact plugs BCTa and BCTb.

On the first and second connection regions CNR1 and CNR2, first and second lower conductive lines (see LCLa and LCLb of FIG. 6B) may be formed which are connected to the cell contact plugs CPLG.

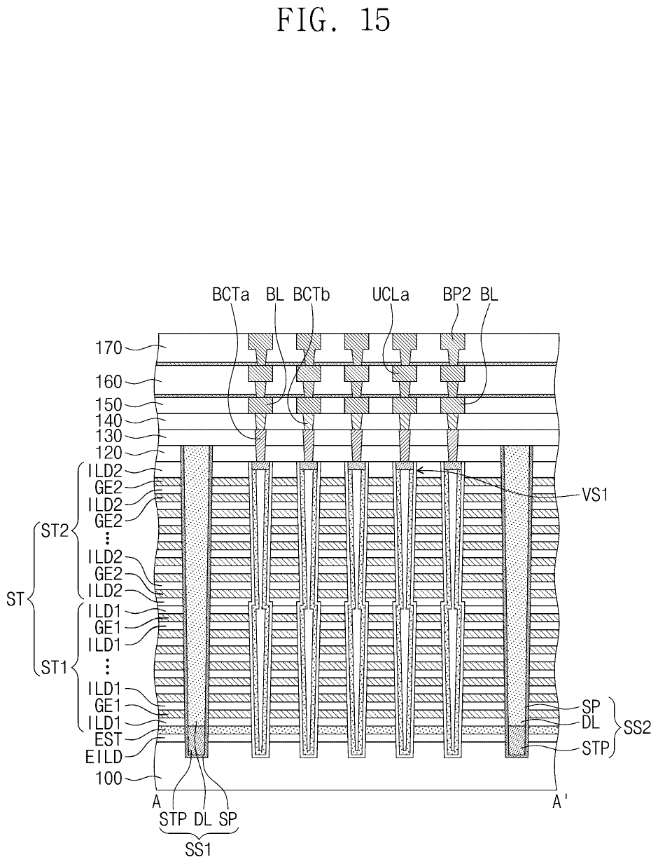

Referring to FIGS. 5 and 15, fourth, fifth, and sixth interlayer dielectric layers 150, 160, and 170 may be formed stacked on the third interlayer dielectric layer 140, and first and second upper conductive lines (see UCLa and UClb of FIG. 6B) may be formed on the third interlayer dielectric layer 140. The first upper conductive lines UCLa may be connected to the bit lines BL. Simultaneously, on the first and second connection regions (see CNR1 and CNR2 of FIG. 6B), the second upper conductive lines (see UCLb of FIG. 6B) may be formed, and the second upper conductive lines (see UCLb of FIG. 6B) may be connected to the first and second lower conductive lines (see LCLa and LCLb of FIG. 6B).

Second bonding pads BP2 may be formed in the sixth interlayer dielectric layer 170, and the second bonding pads BP2 may be connected to the first and second upper conductive lines (see UCLa and UCLb of FIG. 6B).

A damascene process may be used to form the first and second upper conductive lines (see UCLa and UCLb of FIG. 6B) and the second bonding pads BP2. The second bonding pads BP2 may have their top surfaces substantially coplanar with that of the sixth interlayer dielectric layer 170.

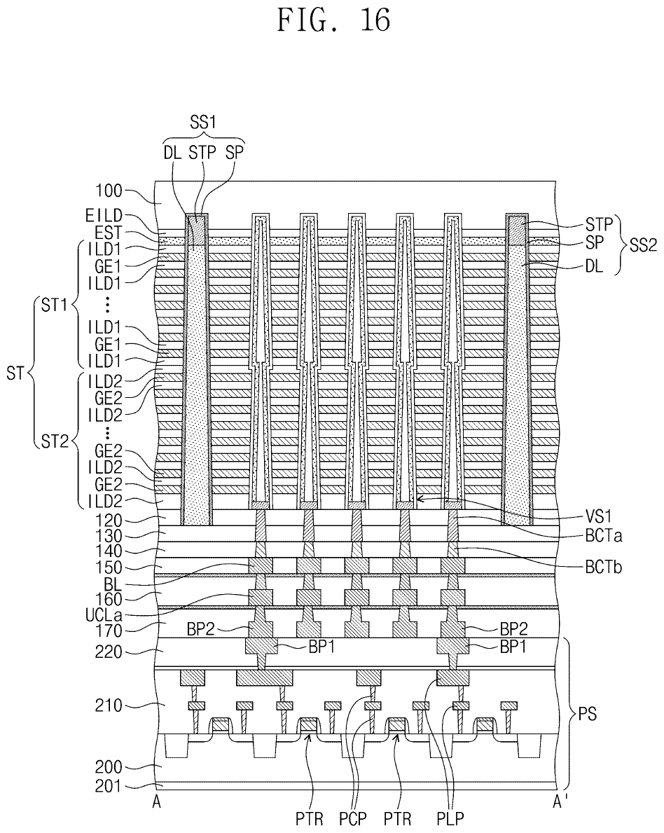

Referring to FIGS. 5 and 16, a peripheral circuit structure PS may be prepared which includes peripheral circuits PTR formed on a second substrate 200.

For example, the formation of the peripheral circuit structure PS may include forming in the second substrate 200 a device isolation layer that defines an active area, forming the peripheral circuits PTR on the active area on the second substrate 200, forming peripheral contact plugs PCP, peripheral circuit lines PLP, first bonding pads BP1 that are electrically connected to the peripheral circuits PTR, and forming peripheral interlayer dielectric layers 210 and 220 that cover the peripheral contact plugs PCP, the peripheral circuit lines PLP, and the first bonding pads BP1.

The second substrate 200 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof. In this description, the second substrate 200 may correspond to a semiconductor substrate.

Row and column decoders, page buffers, and control circuits may be formed as the peripheral circuits PTR on the second substrate 200. The peripheral circuits PTR may include metal oxide semiconductor (MOS) transistors each of which uses the second substrate 200 as a channel.

The peripheral interlayer dielectric layers 210 and 220 may include a single dielectric layer that covers the peripheral circuits PTR or a plurality of stacked dielectric layers that cover the peripheral circuits PTR. For example, the peripheral interlayer dielectric layers 210 and 220 may include a plurality of lower dielectric layers and etch stop layers between the lower dielectric layers. The peripheral interlayer dielectric layers 210 and 220 may include one or more of a silicon oxide layer, a silicon nitride layer, a silicon oxynitride layer, and a low-k dielectric layer.

The peripheral contact plugs PCP may penetrate portions of the peripheral interlayer dielectric layers 210 and 220 to come into connection with the peripheral circuits PTR. The peripheral circuit lines PLP may be formed by depositing a conductive layer and patterning the conductive layer.

The first bonding pads BP1 may be formed in an uppermost one 220 of the peripheral interlayer dielectric layers 210 and 220. The first bonding pads BP1 may be electrically connected to the peripheral circuits PTR through the peripheral contact plugs PCP and the peripheral circuit lines PLP.

A damascene process may be used to form the first bonding pads BP1. The first bonding pads BP1 may have their top surfaces substantially coplanar with that of the uppermost peripheral interlayer dielectric layer 220. In this description below, the phrase “substantially coplanar with” may mean that a planarization process can be performed. The planarization process may include, for example, a chemical mechanical polishing (CMP) process or an etch-back process.

The cell array structure CS formed on the first substrate 100 may be bonded to the peripheral circuit structure PS formed on the second substrate 200. Thus, the first bonding pads BP1 of the peripheral circuit structure PS may be bonded to the second bonding pads BP2 of the cell array structure CS, and an uppermost interlayer dielectric layer 170 on the first substrate 100 may be bonded to the uppermost peripheral interlayer dielectric layer 220 on the second substrate 200.

As the first and second bonding pads BP1 and BP2 are bonded to each other, the cell array structure CS may be turned upside down. For example, the first substrate 100 of the cell array structure CS may be positioned at a top position, and the stepwise structure of the stack structure ST may be disposed upside down.

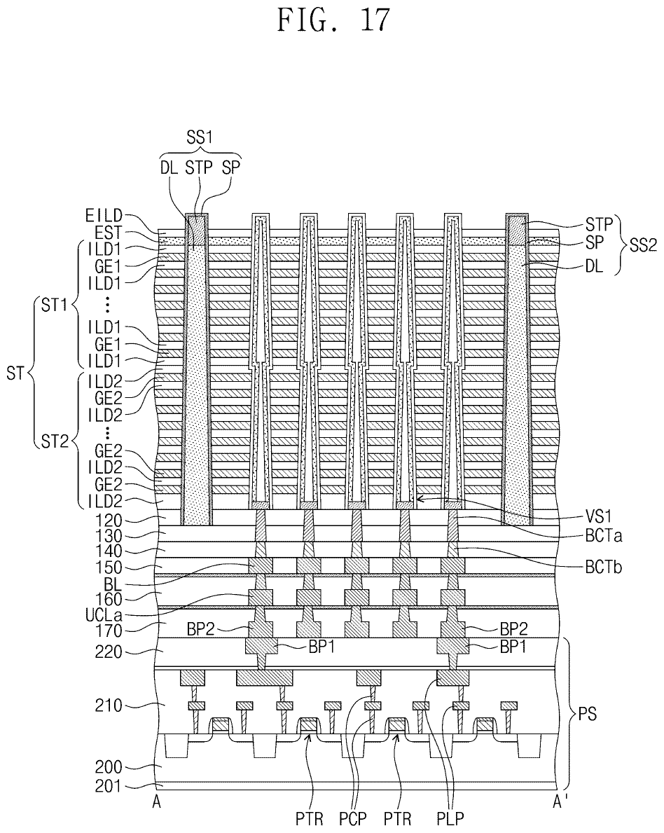

Referring to FIGS. 5 and 17, after the bonding between the first bonding pads BP1 and the second bonding pads BP2, the first substrate 100 may be removed. The first substrate 100 may be removed by a grinding process, a planarization process, a dry etching process, and/or a wet etching process. The removal of the first substrate 100 may expose a top surface of an uppermost interlayer dielectric layer ILD1 of the stack structure ST and a top surface of the first planarized dielectric layer (see 110a of FIG. 6B). In addition, the removal of the first substrate 100 may cause the data storage layers of the first vertical structures VS1 to protrude from the uppermost interlayer dielectric layer ILD1. Simultaneously, the peripheral contact plugs PPLG and the input/output contact plug IOPLG may be exposed.

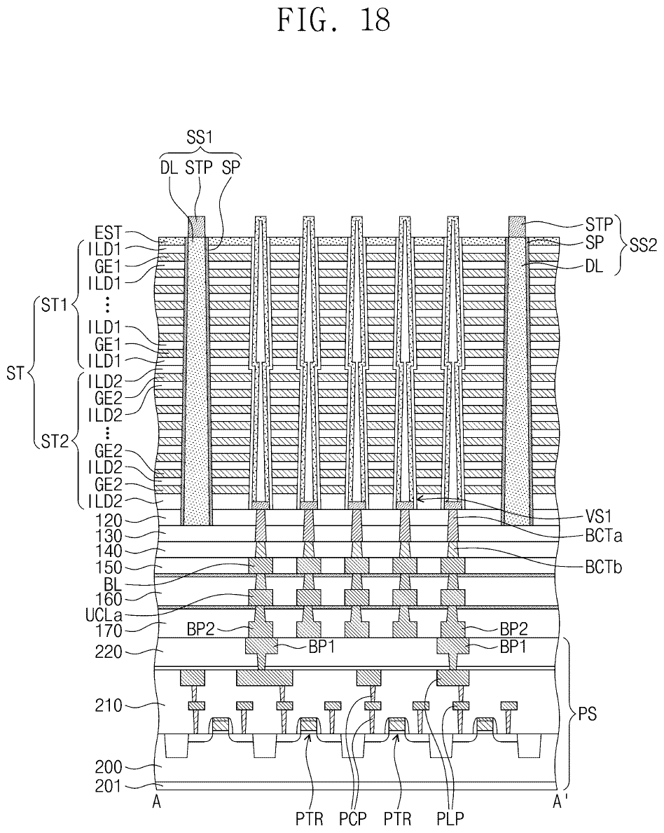

Referring to FIGS. 5 and 18, an upper portion of the data storage layer that protrudes from the uppermost interlayer dielectric layer ILD1 may be removed to expose a top surface of the vertical channel layer and top surfaces of the separation structures SS1 and SS2.

An isotropic etching process may be performed on the upper portion of the data storage layer that protrudes from the top surface of the uppermost interlayer dielectric layer ILD1. Therefore, an upper portion of the vertical channel layer may be exposed, and a data storage pattern (see DSP of FIG. 8) may be formed whose opposite ends are opened.

The isotropic etching process performed on the data storage layer may use an etch recipe having an etch selectivity with respect to a vertical channel pattern (see VP of FIG. 8). The isotropic etching process of the data storage layer may include sequentially isotropically etching a blocking dielectric layer, a charge storage layer, and a tunnel dielectric layer.

For example, the isotropic etching process may include a first etching process that etches a portion of the blocking dielectric layer, a second etching process that etches a portion of the charge storage layer, and a third etching process that etched a portion of the tunnel dielectric layer. An etchant including hydrofluoric acid or sulfuric acid may be used in the first and third etching processes, and an etchant including phosphoric acid may be used in the second etching process. A top surface of the data storage pattern (see DSP of FIG. 8) may have a profile that is changed in accordance with etch recipes of the first, second, and third etching processes.

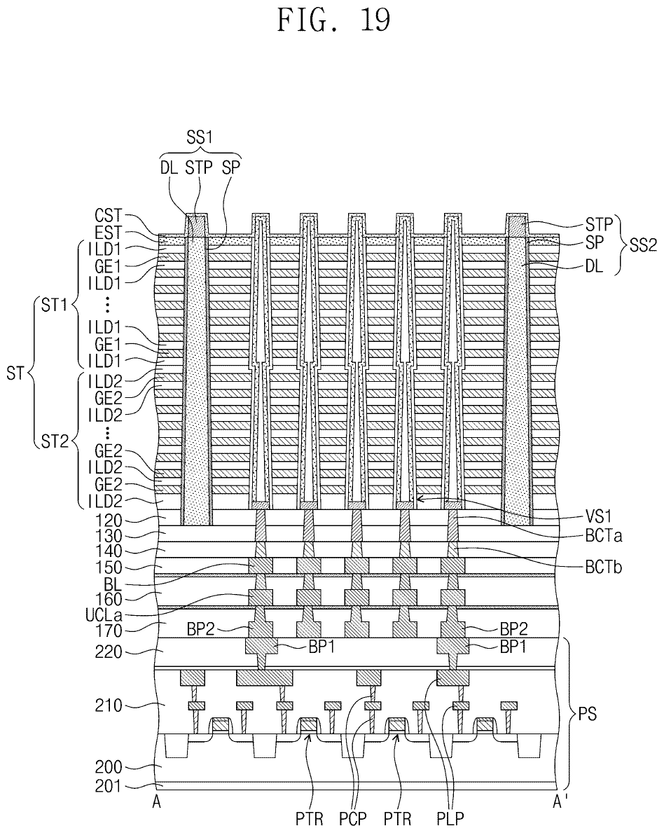

Referring to FIG. 19, a source conductive pattern CST may be deposited on the etch stop layer EST. The source conductive pattern CST may be conformally deposited to cover a top surface of the etch stop layer EST, the top surface of the stop pattern STP, and the vertical channel layer. The source conductive pattern CST may include at least one selected from polysilicon, doped semiconductors (e.g., doped silicon), metals (e.g., tungsten, copper, or aluminum), conductive metal nitrides (e.g., titanium nitride or tantalum nitride), and transition metals (e.g., titanium or tantalum).

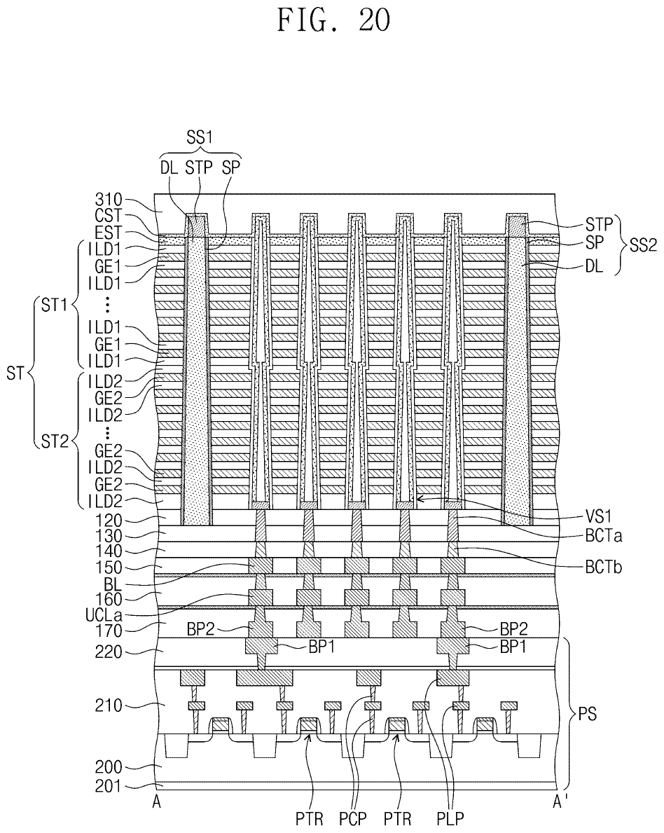

Referring to FIG. 20, an upper dielectric layer 310 may be formed on the source conductive pattern CST.

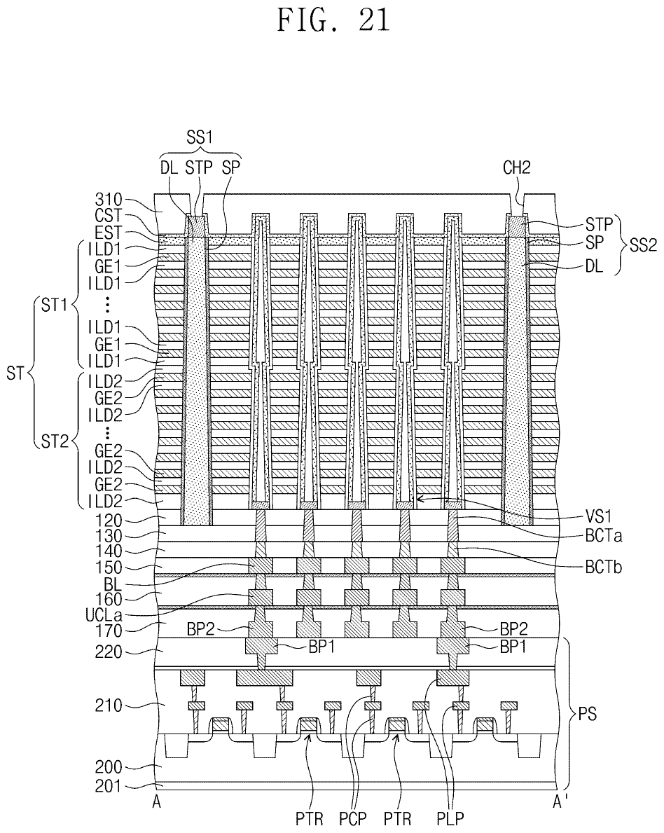

Referring to FIGS. 5 and 21, the upper dielectric layer 310 may be patterned to form a contact hole CH2 that exposes the source conductive pattern CST. During the formation of the contact hole CH2, a portion of the source conductive pattern CST may be etched. According to some embodiments of inventive concepts, even though the source conductive pattern CST is etched, the stop pattern STP may be disposed below the source conductive pattern CST and thus the dielectric pattern DL may be suppressed from being additionally over-etched.

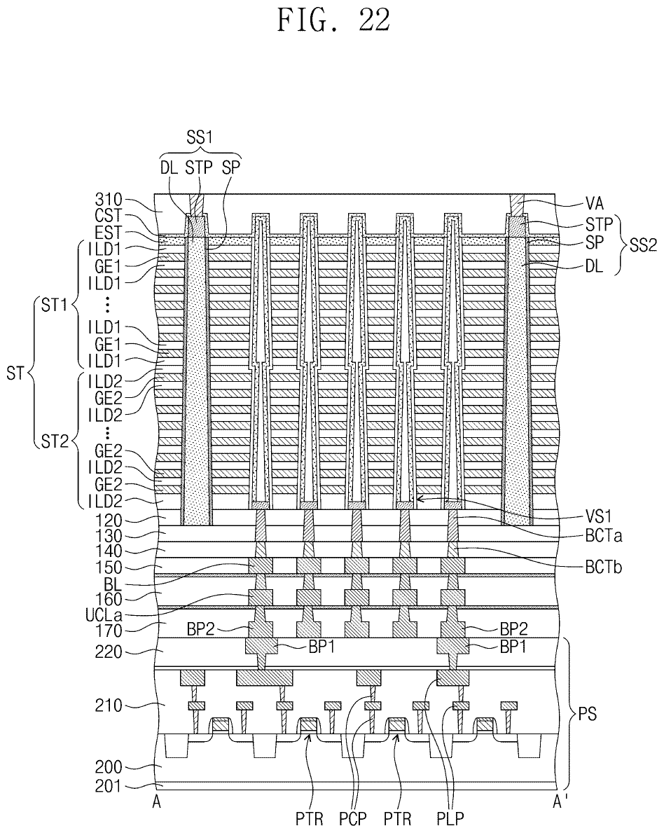

Referring to FIGS. 5 and 22, an upper via VA may be formed on the stop pattern STP. The formation of the upper via VA may include forming a metal barrier layer that covers a bottom surface and an inner wall of the contact hole CH2, filling a conductive material on the metal barrier layer, and performing a planarization process to expose a top surface of the upper dielectric layer 310.

Referring to FIGS. 5, 6B, and 23, wiring patterns PAD and input/output pads IOPAD may be formed on the upper dielectric layer 310. The input/output pad IOPAD may be connected to the input/output contact plug IOPLG through the upper via VA that penetrates the upper dielectric layer 310.

After the formation of the input/output pads IOPAD, a capping dielectric layer 320, a protection layer 330, and a passivation layer 340 may be sequentially formed. The capping dielectric layer 320 may include, for example, a silicon oxide layer, a silicon nitride layer, or a silicon oxynitride layer. The protection layer 330 may include, for example, a silicon nitride layer or a silicon oxynitride layer. The passivation layer 340 may include, for example, a polyimide-based material such as photosensitive polyimide (PSPI). A spin coating process may be employed to form the passivation layer 340 on the protection layer 330.

The capping dielectric layer 320, the protection layer 330, and the passivation layer 340 may be patterned to form an opening OP that exposes a portion of the input/output pad IOPAD.

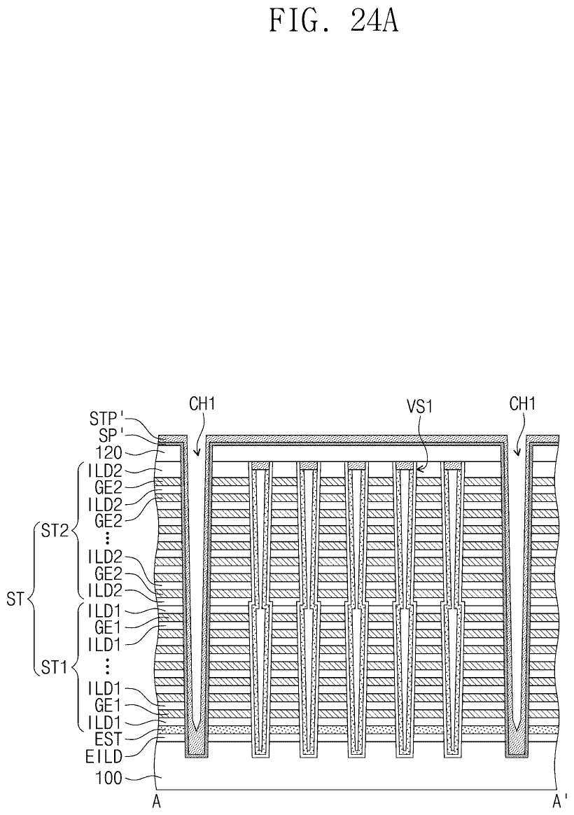

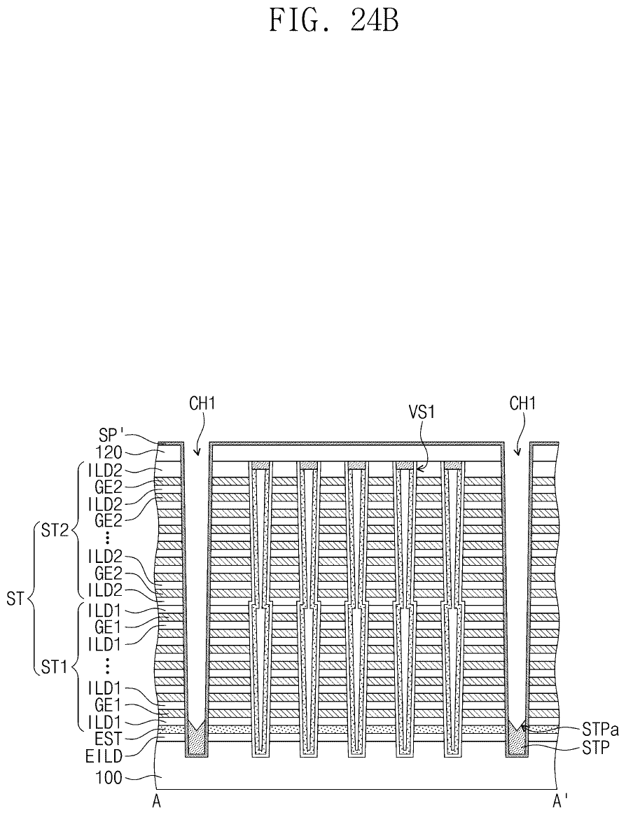

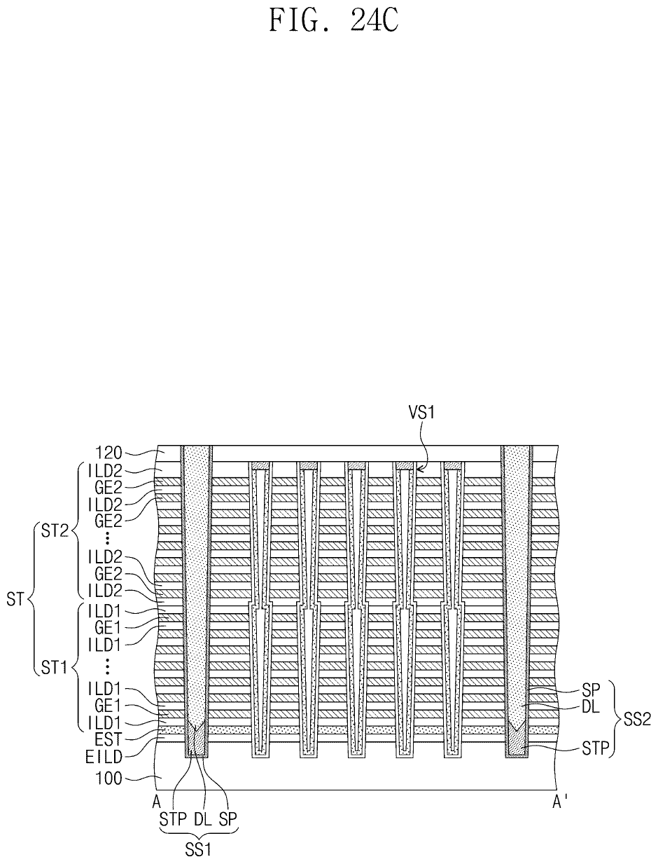

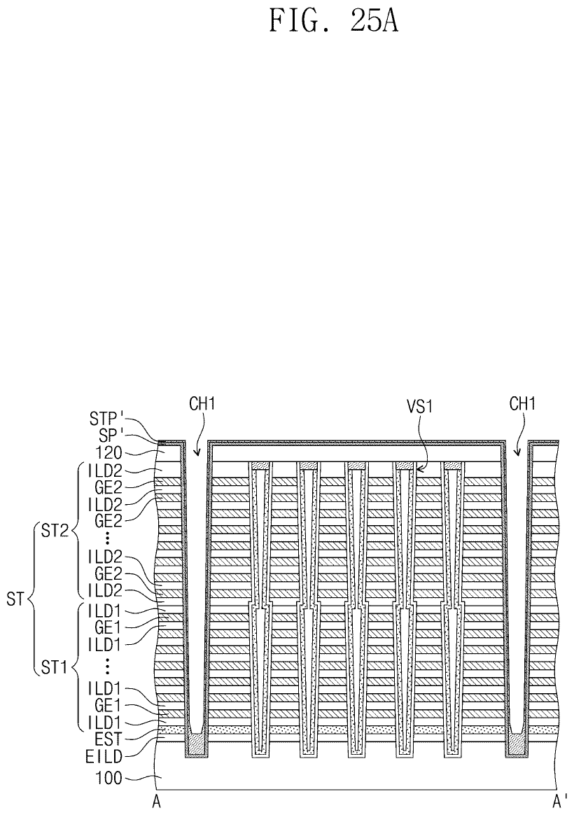

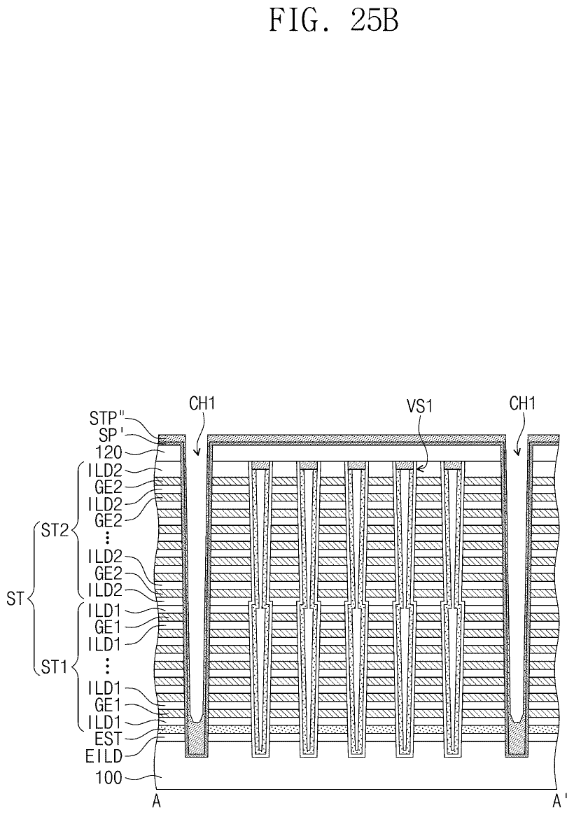

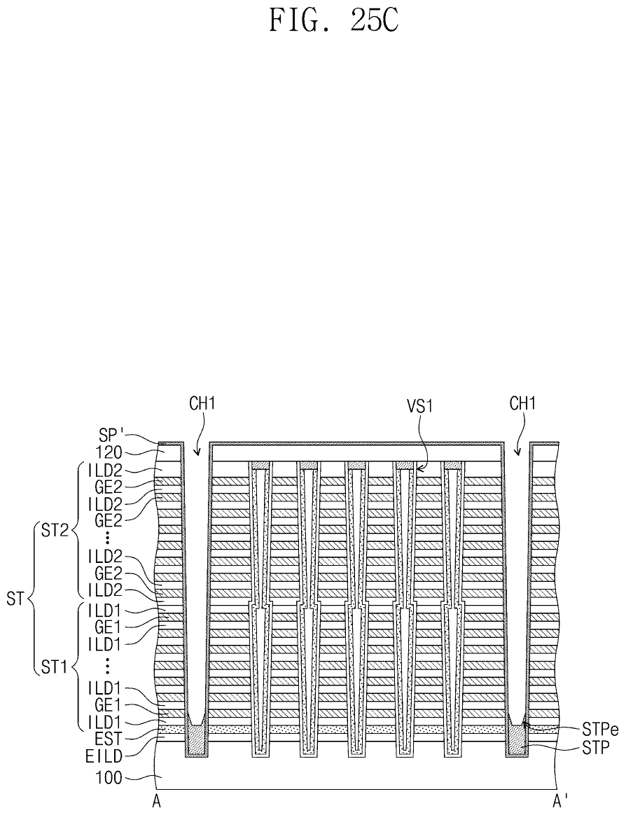

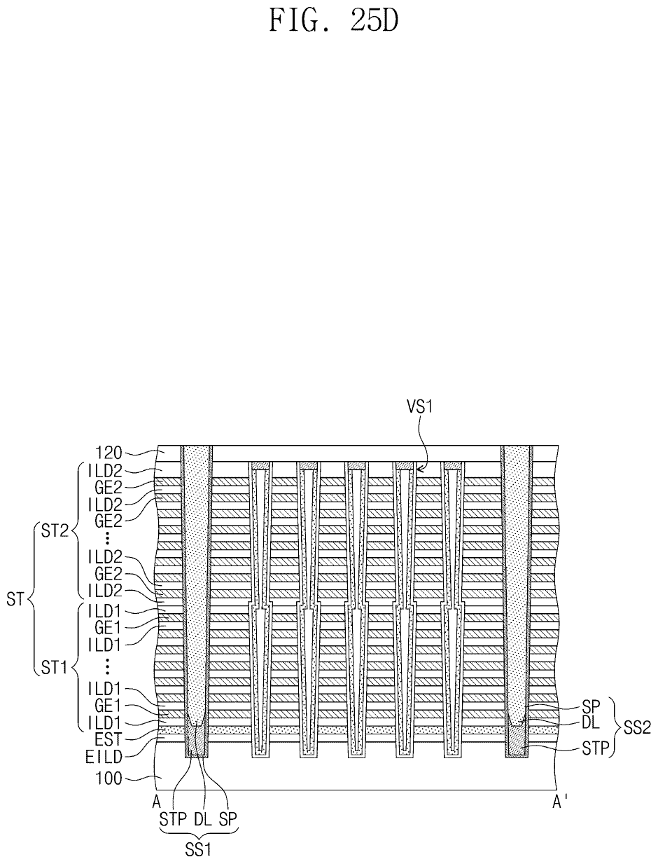

FIGS. 24A to 24C illustrate cross-sectional views showing a method of forming a separation structure in fabricating a semiconductor device according to some embodiments of inventive concepts. FIGS. 25A to 25D illustrate cross-sectional views showing a method of forming a separation structure in fabricating a semiconductor device according to some embodiments of inventive concepts.

Referring to FIG. 24A, a stop layer STP′ may be formed on the spacer layer SP′. The stop layer STP′ may fill only a portion of the trench CH1, and a remaining portion of the trench CH1 may be in an unoccupied state. The stop layer STP′ may fill a portion of the trench CH1 along its inner wall and bottom surface. For example, a chemical vapor deposition (CVD) process may be used to fill the trench CH1 with the stop layer STP′. The stop layer STP′ may include at least one selected from amorphous silicon, polysilicon, and metal.

Referring to FIG. 24B, a portion of the stop layer STP′ may be etched to form a stop pattern STP. For example, the stop layer STP′ may be etch-backed to leave a portion of the stop layer STP′ while removing a remaining portion of the stop layer STP′, such that the stop pattern STP may be formed in a lower portion of the trench CH1. The stop pattern STP may have an exposed top surface STPa including a recess.

Referring to FIG. 24C, a dielectric pattern DL may be filled on the stop pattern STP. For example, the dielectric pattern DL may be formed by using a chemical vapor deposition (CVD) to form a dielectric layer that fills the trench CH1 in which the stop pattern STP is formed, and then performing a planarization process (e.g., CMP) on the dielectric layer to expose the first interlayer dielectric layer 120. The planarization process may remove a portion of the spacer layer SP′ to form a spacer SP. The planarization process may include, for example, a chemical mechanical polishing (CMP) process or an etch-back process.

Alternatively, referring to FIG. 25A, a first stop layer STP′ may be formed on the spacer layer SP′. The first stop layer STP′ may fill only a portion of the trench CH1, and a remaining portion of the trench CH1 may be in an unoccupied state. The first stop layer STP′ may fill a portion of the trench CH1 along its inner wall and bottom surface. For example, a chemical vapor deposition (CVD) process may be used to fill the trench CH1 with the first stop layer STP′. The first stop layer STP′ may include at least one selected from amorphous silicon, polysilicon, and metal.

Referring to FIG. 25B, a second stop layer STP″ may be formed on the spacer layer SP′. The formation of the second stop layer STP″ may include etching a portion of the first stop layer STP′ and refilling a portion of the trench CH1 with a stop pattern material. The partial etching of the first stop layer STP′ may include conformally coating the first stop layer STP′ on the inner wall and the bottom surface of the trench CH1. The stop pattern material may include at least one selected from amorphous silicon, polysilicon, and metal.

Referring to FIG. 25C, the second stop layer STP″ may be etched to form a stop pattern STP. For example, the second stop layer STP″ may be dry-etched to leave a portion of the second stop layer STP″ and to remove a remaining portion of the second stop layer STP″, with the result that the stop pattern STP may be formed. The stop pattern STP may have a lateral surface STPe that partially protrudes.

Referring to FIG. 25D, a dielectric pattern DL may be filled on the stop pattern STP. The dielectric pattern DL may be formed by using a chemical vapor deposition (CVD) to form a dielectric layer that fills the trench CH1 in which the stop pattern STP is formed, and then performing a planarization process (e.g., CMP) on the dielectric layer to expose the first interlayer dielectric layer 120. The planarization process may remove a portion of the spacer layer SP′ to form a spacer SP. The planarization process may include, for example, a chemical mechanical polishing (CMP) process or an etch-back process.

According to some embodiments of inventive concepts, in a semiconductor device including a structure in which a cell array structure and a peripheral circuit structure are bonded to each other, separation structures may include a stop pattern. The stop pattern may limit and/or prevent over-etching when forming a contact hole that penetrates an upper dielectric layer disposed on the separation structure. Moreover, the separation structures may include a dielectric pattern in addition to the stop pattern. Compared to the stop pattern, the dielectric pattern may be less affected by heat-induced warpage, and thus it may be possible to satisfactorily perform a process through which the cell array structure and the peripheral circuit structure are bonded to each other.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although inventive concepts have been described in connection with some embodiments of inventive concepts illustrated in the accompanying drawings, it will be understood to those skilled in the art that various changes and modifications may be made without departing from the technical spirit and essential feature of inventive concepts. It will be apparent to those skilled in the art that various substitution, modifications, and changes may be thereto without departing from the scope and spirit of inventive concepts.

What is claimed is:

1. A semiconductor device, comprising:
a semiconductor substrate;
a peripheral circuit structure including a plurality of peripheral circuits on the semiconductor substrate and a plurality of first bonding pads connected to the peripheral circuits; and
a cell array structure including a plurality of second bonding pads bonded to the first bonding pads, wherein
the cell array structure includes a stack structure, a separation structure penetrating the stack structure, a plurality of vertical channel patterns penetrating the stack structure, a source conductive pattern connected to the vertical channel patterns on the stack structure, an upper dielectric layer covering the source conductive pattern, and an upper via that penetrates the upper dielectric layer,
the stack structure includes a plurality of interlayer dielectric layers and a plurality of conductive patterns that are vertically alternately stacked,
the separation structure includes a dielectric pattern and a stop pattern on the dielectric pattern,
the source conductive pattern is in contact with a top surface of the stop pattern, and
the upper via connects to the source conductive pattern on the stop pattern.

2. The semiconductor device of claim 1, wherein the upper via is in contact with the top surface of the stop pattern.

3. The semiconductor device of claim 1, wherein the stop pattern includes at least one of amorphous silicon, polysilicon, and metal.

4. The semiconductor device of claim 1, wherein the dielectric pattern includes at least one of silicon oxide, silicon nitride, and silicon oxynitride.

5. The semiconductor device of claim 1, wherein a level of a bottom surface of the stop pattern is higher than a level of a top surface of one of the plurality of conductive patterns, the one of the plurality of conductive patterns being most adjacent to the source conductive pattern.

6. The semiconductor device of claim 1, wherein
a bottom surface of the stop pattern includes a recess, and
a top surface of the dielectric pattern is in contact with the recess.

7. The semiconductor device of claim 1, wherein
the stop pattern includes a first stop pattern on the dielectric pattern and a second stop pattern between the first stop pattern and the source conductive pattern, and
a dielectric constant of the second stop pattern is less than a dielectric constant of the first stop pattern.

8. The semiconductor device of claim 1, wherein
the separation structure further includes a spacer between the dielectric pattern and the stack structure and between the stop pattern and the stack structure.

9. The semiconductor device of claim 1, further comprising:
a data storage pattern surrounding an outer sidewall of a vertical channel pattern among the plurality of vertical channel patterns; and
a vertical dielectric pattern in the vertical channel pattern.

10. The semiconductor device of claim 9, wherein a level of a contact surface between the vertical channel pattern and the source conductive pattern is different than a level of a contact surface between the source conductive pattern and the data storage pattern.

11. The semiconductor device of claim 1, further comprising:
an etch stop layer between the stack structure and the source conductive pattern.

12. The semiconductor device of claim 11, wherein an upper portion of the vertical channel pattern and an upper portion of the stop pattern protrude from the etch stop layer.

13. The semiconductor device of claim 12, wherein the source conductive pattern has a uniform thickness covering the etch stop layer, the upper portion of the vertical channel pattern, and the upper portion of the stop pattern.

14. A semiconductor device, comprising:
a semiconductor substrate;
a peripheral circuit structure including a plurality of peripheral circuits on the semiconductor substrate and a plurality of first bonding pads connected to the peripheral circuits; and
a cell array structure including a plurality of second bonding pads bonded to the first bonding pads, wherein
the cell array structure includes
a plurality of separation structures extending in a first direction,
a stack structure between the plurality of separation structures, the stack structure including a plurality of interlayer dielectric layers and a plurality of conductive patterns that are vertically alternately stacked,
a source conductive pattern on the stack structure,
a plurality of vertical channel patterns penetrating the stack structure and connecting to the source conductive pattern;
a plurality of bit lines extending in a second direction while crossing the stack structure and connecting to the vertical channel patterns, the second direction intersecting the first direction,
an upper dielectric layer covering the source conductive pattern,
an upper via penetrating the upper dielectric layer and connecting to the source conductive pattern, and
a wiring pattern on the upper dielectric layer and connecting to the upper via
each of the plurality of separation structures includes a dielectric pattern, a stop pattern on the dielectric pattern and adjacent to the source conductive pattern, and a spacer,
the spacer surrounds the dielectric pattern and at least a portion of the stop pattern, and
a vertical length of the stop pattern is less than a vertical length of the dielectric pattern.

15. The semiconductor device of claim 14, wherein the stop pattern includes at least one of amorphous silicon, polysilicon, and metal.

16. The semiconductor device of claim 14, wherein the dielectric pattern includes at least one of silicon oxide, silicon nitride, and silicon oxynitride.

17. The semiconductor device of claim 14, wherein the upper via is in contact with a top surface of the stop pattern.

18. The semiconductor device of claim 14, wherein
a level of a bottom surface of the stop pattern is higher than a level of a top surface of one of the plurality of conductive patterns most adjacent to the source conductive pattern.

19. The semiconductor device of claim 14, wherein
the stop pattern includes a first stop pattern and a second stop pattern,
the first stop pattern is on the dielectric pattern,
the second stop pattern is between the first stop pattern and the source conductive pattern,
a dielectric constant of the second stop pattern is less than a dielectric constant of the first stop pattern.

20. An electronic system, comprising:
a semiconductor device including a peripheral circuit structure and a cell array structure on the peripheral circuit structure; and
a controller electrically connected through an input/output pad to the semiconductor device, the controller being configured to control the semiconductor device, wherein
the peripheral circuit structure includes a plurality of peripheral circuits integrated on a semiconductor substrate and a plurality of first bonding pads connected to the peripheral circuits,
the cell array structure includes a plurality of second bonding pads bonded to the first bonding pads,
the cell array structure includes a stack structure, a separation structure penetrating the stack structure, a plurality of vertical channel patterns penetrating the stack structure, a source conductive pattern connected to the vertical channel patterns on the stack structure, an upper dielectric layer covering the source conductive pattern, and an upper via that penetrates the upper dielectric layer,
the stack structure includes a plurality of interlayer dielectric layers and a plurality of conductive patterns that are vertically alternately stacked,
the separation structure includes a dielectric pattern and a stop pattern on the dielectric pattern,
the source conductive pattern is in contact with a top surface of the stop pattern, and
the upper via connects to the source conductive pattern on the stop pattern.
